(19) United States
(12) Patent Application Publication
(10) Pub. No.: US 2025/0101346 A1
(43) Pub. Date: Mar. 27, 2025

(54) POST-CHEMICAL MECHANICAL POLISHING CLEANING COMPOSITION, POST-CHEMICAL MECHANICAL POLISHING AND CLEANING TREATMENT METHOD, AND METHOD FOR MANUFACTURING SEMICONDUCTOR SUBSTRATE

(71) Applicant: FUJIMI INCORPORATED, Kiyosu-shi (JP)

(72) Inventors: Masafumi NISHIUMI, Kiyosu-shi (JP); Takahito NAGANO, Kiyosu-shi (JP)

(73) Assignee: FUJIMI INCORPORATED, Kiyosu-shi (JP)

(21) Appl. No.: 18/810,102

(22) Filed: Aug. 20, 2024

(30) Foreign Application Priority Data
Sep. 27, 2023 (JP) 2023-165941

(51) Int. Cl. C11D 7/26; C11D 7/04; C11D 7/32; H01L 21/02; H01L 21/306

(52) U.S. Cl. CPC C11D 7/261; C11D 7/04; C11D 7/265; C11D 7/3209; C11D 7/3218; H01L 21/02057; H01L 21/30625

(57) ABSTRACT

Provided is a mechanism capable of further reducing the number of residues remaining on a surface of a polished object to be polished after CMP. A post-chemical mechanical polishing cleaning composition containing the following components (A) and (B), and having a pH of more than 7.0 and 10.0 or less is provided:
Component (A): a nonionic polymer
Component (B): at least one compound selected from the group consisting of a compound having an amino group and a hydroxyl group, a compound represented by formula (1): H₂N[(CH₂)ₓNR¹]_{y}R², and hexamethylenetetramine.

### CROSS-REFERENCE TO RELATED APPLICATION

The entire disclosure of Japanese Patent Application No. 2023-165941, filed on Sep. 27, 2023, is incorporated herein by reference in its entirety.

### BACKGROUND

### 1. Technical Field

The present invention relates to a post-chemical mechanical polishing cleaning composition, a post-chemical mechanical polishing and cleaning treatment method, and a method for manufacturing a semiconductor substrate.

### 2. Description of Related Art

In recent years, with the trend towards multilayer wiring on a surface of a semiconductor substrate, so-called chemical mechanical polishing (CMP) technologies of physically polishing and flattening a semiconductor substrate have been utilized in the production of a device. CMP is a method for flattening a surface of an object to be polished (material to be polished) such as a semiconductor substrate using a polishing composition (slurry) containing abrasive grains such as silica, alumina, or ceria, an anticorrosive, a surfactant, or the like. The object to be polished (material to be polished) is silicon, polysilicon, silicon oxide, silicon nitride, a wiring or a plug made of a metal or the like, or the like.

A large amount of impurities (also referred to as foreign matters or residues) remain on a surface of a semiconductor substrate after a CMP step. The impurities include abrasive grains derived from the polishing composition used in CMP, metals, organic substances such as anticorrosives or surfactants, silicon-containing materials and metals produced by polishing silicon-containing materials which are an object to be polished, metal wirings, plugs, and the like, and, further, organic substances such as pad scraps produced from various pads, and the like.

Contamination of the surface of the semiconductor substrate with these impurities may adversely affect electrical characteristics of a semiconductor and reduce reliability of a device. Therefore, it is desirable to introduce a surface treatment step after the CMP step to remove these impurities from the surface of the semiconductor substrate.

As such a cleaning composition, for example, JP 2015-189899 A (corresponding to US 2017/0175053 A1) discloses a polishing composition containing an organic compound containing a specific atom and having a molecular weight of 100 or more, a pH adjusting agent, and 0 to 1% by mass of abrasive grains.

### SUMMARY

According to the polishing composition disclosed in JP 2015-189899 A (corresponding to US 2017/0175053 A1), impurities remaining on the surface of the object to be polished after CMP can be sufficiently removed. However, as quality required for a semiconductor substrate is becoming higher, a technique capable of more efficiently and more sufficiently removing foreign matters (residues) on a surface of a semiconductor substrate has been required.

Therefore, the present invention has been made in view of the above circumstances, and an object of the present invention is to provide a mechanism capable of further reducing the number of residues remaining on a surface of a polished object to be polished after CMP.

The present inventors have conducted extensive studies to solve the problem. As a result, the present inventors have found that the problem can be solved by an alkaline post-chemical mechanical polishing cleaning composition containing a specific amino group-containing compound and a nonionic polymer, and have completed the present invention.

To be specific, the above object can be achieved by a post-chemical mechanical polishing cleaning composition that contains the following components (A) and (B), and has a pH of more than 7.0 and 10.0 or less:
Component (A): a nonionic polymer
Component (B): at least one compound selected from the group consisting of compounds having an amino group and a hydroxyl group, compounds represented by the following formula (1), and hexamethylenetetramine;

H₂N[(CH₂)ₓNR¹]_{y}R² Formula (1):
in the formula (1), R¹ is each independently a hydrogen atom or an alkyl group having 1 to 10 carbon atoms; R² is a hydrogen atom or an alkyl group having 1 to 10 carbon atoms; x is each independently an integer of 1 or more and 10 or less; and y is an integer of 1 or more and 8 or less.

### DETAILED DESCRIPTION OF THE EMBODIMENTS

The present invention is to provide a post-chemical mechanical polishing cleaning composition including the following components (A) and (B), and having a pH of more than 7.0 and 10.0 or less:
Component (A): a nonionic polymer
Component (B): at least one compound selected from the group consisting of a compound having an amino group and a hydroxyl group, a compound represented by the following formula (1), and hexamethylenetetramine

H₂N[(CH₂)ₓNR¹]_{y}R² Formula (1):
in the above formula (1), R¹ is each independently a hydrogen atom or an alkyl group having 1 to 10 carbon atoms; R² is a hydrogen atom or an alkyl group having 1 to 10 carbon atoms; x is each independently an integer of 1 or more and 10 or less; and y is an integer of 1 or more and 8 or less. According to the present invention, the number of residues remaining on a surface of a polished object to be polished after CMP can be further reduced.

The post-chemical mechanical polishing cleaning composition is intended to be a composition used in a cleaning step performed after chemical mechanical polishing (CMP), and is used to clean a polished object to be polished after chemical mechanical polishing (CMP). In the present description, the post-chemical mechanical polishing cleaning composition having the above configuration is hereinafter also referred to as “the post-chemical mechanical polishing cleaning composition according to the present invention”, “the post-CMP cleaning composition”, or “the post-CMP cleaning composition according to the present invention”.

According to such a post-chemical mechanical polishing cleaning composition (post-CMP cleaning composition) according to the present invention, residues (for example, an abrasive grain residue(s), in particular a silicon compound(s), an organic residue(s)) remaining on a surface of a polished object to be polished (in particular, a polished substrate having a silicon-silicon bond) can be more efficiently and more sufficiently removed.

The present inventors presume a mechanism by which residues on the surface of the polished object to be polished can be removed by such a configuration as follows.

The post-chemical mechanical polishing cleaning composition according to the present invention contains specific components (A) and (B). Among these, the component (A) is adsorbed to a surface of a polished object to be polished by hydrophobic interaction and acts like a protective film. In addition, the component (A) improves wettability of the surface of the polished object to be polished and makes it easier to form a water molecule film on the surface. As a result, the post-chemical mechanical polishing cleaning composition according to the present invention containing the component (A) can not only suppress adhesion of hydrophobic organic residues to the surface of the polished object to be polished but also prevent re-adhesion of the organic residues. Therefore, according to the post-CMP cleaning composition according to the present invention, residues can be efficiently removed.

The component (B) is at least one compound selected from the group consisting of compounds having an amino group and a hydroxyl group, compounds represented by formula (1): H₂N[(CH₂)ₓNR¹]_{y}R², and hexamethylenetetramine. That is, the component (B) has a total of two or more amino groups (a primary amino group, a secondary amino group and a tertiary amino group) and hydroxyl groups (—OH) (hereinafter, also collectively referred to as “interactive groups”). It is considered that the amino group (in particular, a lone electron pair or cation present on a nitrogen atom of the amino group) and the hydroxyl group (in particular, positively (δ+) and negatively (δ−) polarized hydroxyl groups (—O⁻H⁺)) interact with the component (A) (in particular, a positively (δ+) and negatively (δ−) polarized group present in the component (A) (for example, a hydroxyl group (—O—H⁺) or a carbonyl group (—C⁺(═O⁻))) under alkaline conditions (for example, an amino group is hydrogen-bonded with the group in the component (A)). When these interactive groups interact with two components (A) to connect the components (A) or are bonded (crosslinked) to two different portions of one component (A), a thicker protective film of the component (A) is formed on the surface of the polished object to be polished. Further, since the component (B) has a nitrogen atom, it is considered that the component (B) is relatively easily adsorbed to the surface of the polished object to be polished (in particular, a negatively charged polished substrate having a silicon-silicon bond) by electrostatic attraction. For this reason, the component (A) is firmly adsorbed onto the surface of the polished object to be polished via the component (B). At the same time, the component (B) adsorbed on the surface of the polished object to be polished performs a nucleophilic attack on each atom constituting the polished object to be polished, and extends the bond formed by the atom (in particular, silicon-silicon bond) to make it easier to cut. As a result, it is presumed that etching of the surface of the polished object to be polished is promoted, and the surface of the polished object to be polished is peeled off by the etching, and at the same time, residues are removed (the number of residues can be reduced). In particular, in a case where the component (B) has a primary amino group (—NH₂), a cation (—NH₃⁺) of the primary amino group is bonded to an anion of the polished object to be polished (particularly amorphous silicon) by electrostatic attraction, while the other interactive group interacts with the component (A), allowing the component (A) to be bonded to the polished object to be polished more thickly and more firmly, thereby enabling residues to be removed more efficiently.

It should be noted that the above mechanism is based on speculation, and the present invention is not limited to the above mechanism.

In the present description, the amino group is not particularly limited, and includes a primary amino group (—NH₂), a secondary amino group (—NHR; R is an alkyl group having 1 to 30 (preferably 1 to 20, more preferably 1 to 10) carbon atoms or an aryl group having 6 to 30 (preferably 6 to 20) carbon atoms), and a tertiary amino group (—NR₂; R's are each independently an alkyl group having 1 to 30 (preferably 1 to 20, more preferably 1 to 10) carbon atoms or an aryl group having 6 to 30 (preferably 6 to 20) carbon atoms). Further, the amino group may be a combination of the primary to tertiary amino groups. Furthermore, in a case where multiple (two or more) amino groups are present, these amino groups may be linked to each other to form —NR′—NR″— (wherein R′ and R″ are each independently a hydrogen atom, an alkyl group having 1 to 30 (preferably 1 to 20, more preferably 1 to 10) carbon atoms, or an aryl group having 6 to 30 (preferably 6 to 20) carbon atoms). However, the amino group does not include a quaternary ammonium salt (—NR₄⁺·X⁻).

In the present description, the hydroxyl group is intended to be —OH itself, and does not include a group having an —OH group (for example, a carboxyl group).

Throughout the description, the expression a singular form should be understood to include the concept of its plural form, unless otherwise stated. Thus, singular articles (for example, “a”, “an”, “the”, and the like in English) should be understood to include the concept of its plural form as well, unless otherwise stated. Further, terms used herein should be understood to be used in the sense commonly used in the art unless otherwise stated. Thus, unless otherwise defined, all the technical terms and scientific terms used herein have the same meaning as commonly understood by one of ordinary skill in the art to which the present invention is pertained. If there is any conflict in meaning, the present description (including the definitions) takes priority.

Hereinafter, embodiments of the present invention will be described in detail, but the present invention is not limited to only the following embodiments, and can be modified in various ways within the scope of claims. Further, the embodiments described in the present description can be other embodiments by arbitrarily combining the embodiments. In the present description, unless otherwise specified, operations and measurements of physical properties and the like are performed under conditions of room temperature (20° C. or more and 25° C. or less)/relative humidity of 40% RH or more and 50% RH or less. Further, “X and/or Y” means to include each of X and Y and a combination thereof.

### [Residue(s)]

In the present description, the residue(s) represents a foreign matter(s) adhering to a surface of a polished object to be polished. Examples of the residue are not particularly limited, but may include a residue(s) derived from an object to be polished, an organic residue(s) which will be described later, a particle residue(s) derived from abrasive grains contained in the polishing composition (abrasive grain residue(s)), a residue(s) composed of components other than the particle residue(s) and the organic residue(s), and other residues such as a mixture of the particle residue(s) and the organic residue(s).

The total number of residues represents the total number of all residues regardless of the type. The total number of residues can be measured using a wafer defect inspection apparatus. The number of residues represents the total number of a specific residue. Details of a method for measuring the number of residues will be described in Examples to be described later.

In the present description, the organic residue(s) represents a component(s) composed of an organic substance(s) such as an organic low-molecular compound(s) or an organic polymer compound(s), an organic salt(s), or the like, among foreign matters adhering to a surface of a polished object to be polished (object to be subjected to surface treatment).

Examples of the organic residue(s) adhering to a polished object to be polished may include pad debris generated from a pad used in a polishing step or a rinse polishing step to be described later, component(s) derived from an additive(s) contained in a polishing composition used in a polishing step or a post-CMP cleaning composition used in a rinse polishing step, and the like.

Since organic residue(s) and other foreign matters are greatly different in color and shape, it is possible to visually determine whether or not a foreign matter(s) is an organic residue by observation with SEM. Further, whether or not the foreign matter is an organic residue may be determined by elemental analysis using an energy dispersive X-ray analyzer (EDX) as necessary. The number of organic residues can be measured using a wafer defect inspection apparatus and SEM or EDX elemental analysis.

The abrasive grain residue(s) adhering to a polished object to be polished is a particle residue(s) derived from abrasive grain(s) contained in a polishing composition. Examples of the abrasive grains may include particles made of a metal oxide such as a silicon compound such as silica (silicon oxide), an aluminum compound such as alumina, a zirconium compound such as zirconia, and a titanium compound such as titania. The abrasive grain residue(s) may be derived from the single kind of abrasive grain or from a mixture of two or more kinds of abrasive grains. Among these, in a case where the abrasive grain residue(s) is a residue derived from a silicon compound such as silica (particularly colloidal silica), an effect(s) by the present invention can be particularly remarkably exhibited. Therefore, in one embodiment of the present invention, the post-chemical mechanical polishing cleaning composition is a post-chemical mechanical polishing cleaning composition for removing a silicon compound(s). In one embodiment of the present invention, the post-chemical mechanical polishing cleaning composition is a post-chemical mechanical polishing cleaning composition for removing a silica abrasive grain residue(s). In one embodiment of the invention, the post-chemical mechanical polishing cleaning composition is a post-chemical mechanical polishing cleaning composition for removing a colloidal silica abrasive grain residue(s).

### [Polished Object to be Polished]

In the present description, the polished object to be polished refers to an object to be polished which has been polished in a polishing step. The polishing step is a chemical mechanical polishing (CMP) step.

A material contained in the polished object to be polished according to the present invention is not particularly limited, but a Si-based material is preferable from a viewpoint that sufficient etching can be promoted by adsorption of the component (A) and the effect(s) by the present invention can be easily obtained. Examples of the Si-based material may include a material having a silicon-silicon bond (silicon material), a material having a nitrogen-silicon bond, a material having an oxygen-silicon bond, and the like. The polished object to be polished may be made of a plurality of materials among the materials.

Among these, the material contained in the polished object to be polished is preferably a material having a silicon-silicon bond (silicon material) because the effect(s) by the post-CMP cleaning composition according to one embodiment of the present invention can be more remarkably obtained. To be specific, the post-CMP cleaning composition according to one embodiment of the present invention is preferably used for post-chemical mechanical polishing and cleaning treatment (surface treatment) of a substrate having a surface composed of a material having a silicon-silicon bond (silicon material).

Examples of the material having a silicon-silicon bond may include polysilicon (polycrystalline silicon), amorphous silicon, single crystal silicon, and the like. These materials may be doped with impurities. In this case, the impurities may be either n-type or p-type. Examples of the p-type impurities may include group 13 elements such as boron (B), aluminum (Al), gallium (Ga), and indium (In). Examples of the n-type impurities may include group 15 elements such as phosphorus (P), arsenic (As), bismuth (Bi), and antimony (Sb).

In one embodiment of the present invention, the material having a silicon-silicon bond (silicon material) contains at least one material selected from the group consisting of polysilicon, amorphous silicon, and single crystal silicon. From a viewpoint that the effect(s) by the present invention can be more remarkably obtained, the material having a silicon-silicon bond (silicon material) is more preferably polysilicon, amorphous silicon or single crystal silicon, still more preferably polysilicon or amorphous silicon, and particularly preferably amorphous silicon. To be specific, the post-chemical mechanical polishing cleaning composition according to one embodiment of the present invention is more preferably used for post-chemical mechanical polishing and cleaning treatment (post-CMP cleaning treatment, surface treatment) of a substrate (polished object to be polished) having a surface made of polysilicon, amorphous silicon or single crystal silicon. The post-chemical mechanical polishing cleaning composition according to one embodiment of the present invention is still more preferably used for post-chemical mechanical polishing and cleaning of a substrate (polished object to be polished) having a surface made of polysilicon or amorphous silicon. The post-chemical mechanical polishing cleaning composition according to one embodiment of the present invention is particularly preferably used for post-chemical mechanical polishing and cleaning of a substrate (polished object to be polished) having a surface made of amorphous silicon.

### [Post-Chemical Mechanical Polishing Cleaning Composition (Post-CMP Cleaning Composition)]

The post-chemical mechanical polishing cleaning composition (post-CMP cleaning composition) according to the present invention is used to reduce residues on a surface of a polished object to be polished.

### <Component (A)>

The post-chemical mechanical polishing cleaning composition according to the present invention contains a nonionic polymer as the component (A). The term “nonionic polymer” as used herein refers to a polymer that does not have an anionic group such as a carboxylic acid group, a sulfonic acid group, or a phosphoric acid group, and a cationic group such as a quaternary ammonium group, in its molecule.

The nonionic polymer acts as a protective film on a surface of a polished object to be polished. Further, the nonionic polymer can improve wettability of a surface of a polished object to be polished without inhibiting control (positively charging) of the zeta potential of the polished object to be polished, an abrasive grain residue(s), an organic residue(s), and the like by the component (B). Accordingly, the presence of the component (A) can promote removal of residues on the surface of the polished object to be polished (suppress adhesion and re-adhesion of organic residue(s) and the like).

The nonionic polymer can be a polymer having the same (homopolymer) or different (copolymer) repeating units, typically a compound having a weight average molecular weight (Mw) of 1,000 or more. In a case where the nonionic polymer is a copolymer, the copolymer may be any of a block copolymer, a random copolymer, a graft copolymer, or an alternating copolymer.

Examples of the nonionic polymer may include polyvinyl alcohol, polyvinylpyrrolidone, polyacrylamide, poly N-vinylacetamide, polyamines, polyvinyl ethers (polyvinyl methyl ether, polyvinyl ethyl ether, polyvinyl isobutyl ether, and the like), polyglycerin, polyethylene glycol, polypropylene glycol, water-soluble polysaccharides such as hydroxyethyl cellulose, alginic acid polyhydric alcohol esters, water-soluble urea resins, dextrin derivatives, casein, and the like. Further, not only those having such a main chain structure, but also a graft copolymer having a nonionic polymer structure in its side chain can be suitably used. Furthermore, copolymers such as an ethylene-vinyl alcohol copolymer and a butenediol-vinyl alcohol copolymer can also be used. These nonionic polymers can be used solely or in combination of two or more kinds thereof.

Among these, from a viewpoint of further improving the effect(s) of removing residues, the nonionic polymer preferably includes (1) a nonionic polymer containing a nitrogen atom and/or (2) a nonionic polymer containing a hydroxyl group (hydroxy group).

Suitable examples of the nonionic polymer of the (1) and/or (2) as above may include the following: polyvinyl alcohol, polyvinylpyrrolidone, polyacrylamide, poly N-vinylacetamide, polyethylene glycol, hydroxyethyl cellulose, a butenediol-vinyl alcohol copolymer, and the like. Therefore, in one embodiment, the nonionic polymer as the component (A) preferably contains at least one selected from the group consisting of polyvinyl alcohol, polyvinylpyrrolidone, polyacrylamide, poly N-vinylacetamide, polyethylene glycol, hydroxyethyl cellulose, and a butenediol-vinyl alcohol copolymer. In still another embodiment, the nonionic polymer preferably contains at least one selected from the group consisting of polyvinyl alcohol, polyvinylpyrrolidone, and poly N-vinylacetamide. In still another embodiment, the nonionic polymer preferably contains polyvinyl alcohol or polyvinylpyrrolidone. In still another embodiment, the nonionic polymer preferably contains polyvinyl alcohol. In still another embodiment, the nonionic polymer is preferably polyvinyl alcohol. Since these nonionic polymers are easily adsorbed on a surface of a polished object to be polished (in particular, a polished object to be polished containing a silicon-silicon bond), a water molecule film can be more easily formed. As a result, in particular, adhesion and re-adhesion of organic residue(s) can be effectively suppressed, and the effect of removing the residues can be further improved.

The reason why the nonionic polymers of the above (1) and (2) are preferable as the nonionic polymer is considered as follows.

In a case where a nonionic polymer containing a nitrogen atom is used as in the above (1), the nitrogen atom contained in the nonionic polymer and a hydroxyl group (—OH) present on a surface of a substrate (polished object to be polished) having a surface made of a silicon material are easily polarized positively (δ+) and negatively (δ−), respectively, and thus the nonionic polymer is easily adsorbed to the surface of the substrate (polished object to be polished) having a surface made of a silicon material. Thus, it is considered that as a result of facilitating formation of a water molecule film as described above, adhesion and re-adhesion of organic residue(s) can be effectively suppressed. Therefore, in one embodiment of the present invention, the nonionic polymer preferably contains a nitrogen atom. In the above embodiment, the nonionic polymer preferably contains at least one selected from the group consisting of polyvinylpyrrolidone, polyacrylamide, and poly N-vinylacetamide. Furthermore, the nonionic polymer more preferably contains polyvinylpyrrolidone and/or poly N-vinylacetamide. Furthermore, the nonionic polymer further preferably contains polyvinylpyrrolidone. Furthermore, the nonionic polymer is particularly preferably polyvinylpyrrolidone.

Also in a case where a nonionic polymer containing a hydroxyl group (—OH) is used as in the above (2), since the nonionic polymer is relatively easily adsorbed to a surface of a substrate (a polished object to be polished) having a surface made of a silicon material, it is considered that a water molecule film can be easily formed as described above, and as a result, adhesion and re-adhesion of organic residue(s) can be effectively suppressed. Here, the present inventors have found that the effect of reducing residues can be particularly improved in a case where the component (B) according to the present invention is used in combination in the form of the above (2). To be specific, it is considered that two or more interactive groups (an amino group (a primary amino group, a secondary amino group and a tertiary amino group) and a hydroxyl group (—OH)) present in the component (B) more easily interact with the hydroxyl group (—OH) contained in the component (A) under alkaline conditions, and the hydroxyl group of the component (A) is more efficiently and more firmly bonded to the interactive groups of the component (B). As a result, a thicker protective film of the component (A) can be formed on a surface of a polished object to be polished. Further, the component (A) is also easily adsorbed on a polished object to be polished by the component (B) adsorbed on the polished object to be polished. To be specific, the component (B) having two or more interactive groups makes it easier for the component (A) to form a thicker protective film (water molecule film) more firmly on a surface of a polished object to be polished. Therefore, it is considered that wettability of the surface of the polished object to be polished can be further improved, and adhesion and re-adhesion of organic residue(s) can be effectively suppressed. The above effect is particularly remarkable in a case where the component (B) has two or more amino groups. It should be noted that the above mechanism is based on speculation, and the present invention is not limited to the above mechanism.

Therefore, in one embodiment of the present invention, the nonionic polymer contains a hydroxyl group. In the embodiment, the nonionic polymer preferably contains at least one selected from the group consisting of polyvinyl alcohol, polyethylene glycol, hydroxyethyl cellulose, and a butenediol-vinyl alcohol copolymer. Furthermore, the nonionic polymer more preferably contains polyvinyl alcohol. Furthermore, the nonionic polymer is particularly preferably polyvinyl alcohol.

A lower limit of a weight average molecular weight (Mw) of the nonionic polymer is preferably 1,000 or more, more preferably 3,000 or more, still more preferably more than 5,000, particularly preferably 8,000 or more, and most preferably more than 9,000. Further, an upper limit of the weight average molecular weight (Mw) of the nonionic polymer is preferably 1,000,000 or less, more preferably 100,000 or less, still more preferably 80,000 or less, particularly preferably 50,000 or less, and most preferably less than 50,000. As an example, the weight average molecular weight (Mw) of the nonionic polymer is preferably 1,000 or more and 1,000,000 or less, more preferably 3,000 or more and 100,000 or less, still more preferably more than 5,000 and 80,000 or less, particularly preferably 8,000 or more and 50,000 or less, and most preferably more than 9,000 and less than 50,000.

The weight average molecular weight (Mw) of the nonionic polymer can be measured as a value in terms of polyethylene glycol using gel permeation chromatography (GPC), and details of the measurement method will be described in Examples to be described later.

The nonionic polymer that can be used as the component (A) may be manufactured by synthesis or may be a commercially available product. Examples of the commercially available product may include JMR (registered trademark)-10HH and JMR (registered trademark)-3HH (both manufactured by JAPAN VAM & POVAL Co., Ltd.), Pitzcol (registered trademark) K30A and K30L (both manufactured by DKS Co. Ltd.), CMC Daicel (registered trademark) 1150 and 1170 (both manufactured by Daicel Miraizu Ltd.), GE191-104 and GE191-107 (both manufactured by Showa Denko K.K.), and the like.

The nonionic polymer as the component (A) can be used solely or in combination of two or more kinds thereof.

A content of the component (A) in the post-chemical mechanical polishing cleaning composition (post-CMP cleaning composition) is appropriately set depending on the type of the component (A) to be used and the desired effect. The content of the component (A) is preferably 0.0001% by mass or more, more preferably 0.001% by mass or more, still more preferably 0.01% by mass or more, and particularly preferably 0.03% by mass or more, with a total mass of the post-CMP cleaning composition being 100% by mass (relative to the post-CMP cleaning composition). Further, the upper limit of the content of the component (A) in the post-CMP cleaning composition is preferably 1.5% by mass or less, more preferably 1.0% by mass or less, still more preferably 0.5% by mass or less, and particularly preferably 0.3% by mass or less, with the total mass of the post-CMP cleaning composition being 100% by mass (relative to the post-CMP cleaning composition). In one embodiment of the present invention, the content of the component (A) is 0.0001% by mass or more and 1.5% by mass or less, with the total mass of the post-CMP cleaning composition being 100% by mass (relative to the post-CMP cleaning composition). In one embodiment of the present invention, the content of the component (A) is 0.001% by mass or more and 1.0% by mass or less, with the total mass of the post-CMP cleaning composition being 100% by mass (relative to the post-CMP cleaning composition). In one embodiment of the present invention, the content of the component (A) is 0.01% by mass or more and 0.5% by mass or less, with the total mass of the post-CMP cleaning composition being 100% by mass (relative to the post-CMP cleaning composition). In one embodiment of the present invention, the content of the component (A) is 0.03% by mass or more and 0.3% by mass or less, with the total mass of the post-CMP cleaning composition being 100% by mass (relative to the post-CMP cleaning composition). In a case where the post-CMP cleaning composition contains two or more kinds of component (A), the content of the component (A) is intended to be a total amount thereof.

### <Component (B)>

The post-chemical mechanical polishing cleaning composition according to the present invention contains, as the component (B), at least one compound selected from the group consisting of a compound having an amino group (a primary, a secondary or a tertiary amino group) and a hydroxyl group (—OH), a compound represented by formula (1): H₂N[(CH₂)ₓNR¹]_{y}R², and hexamethylenetetramine. The component (B) may contain an atom(s) other than a carbon atom, a hydrogen atom, a nitrogen atom, and an oxygen atom (other atoms), but preferably contains no other atoms (that is, the component (B) is composed of only a carbon atom, a hydrogen atom, a nitrogen atom, and an oxygen atom, or composed of only a carbon atom, a hydrogen atom and a nitrogen atom).

The compound having an amino group and a hydroxyl group as the component (B) may be a compound having one or more amino groups (a primary amino group, a secondary amino group, or a tertiary amino group) and one or more hydroxyl groups (the hydroxyl group includes the form of a salt). Specific examples thereof may include 2-aminoethanol, 1-amino-2-propanol, 3-amino-1-propanol, diethanolamine, triethanolamine, 2-(2-aminoethylamino)ethanol, tris(hydroxymethyl)aminomethane, 2-(methylamino)ethanol, 2-(2-aminoethoxy)ethanol, 2-amino-2-methyl-1-propanol, 1-dimethylamino-2-propanol, 3-amino-1,2-propanediol, 2-amino-1,3-propanediol, 2-amino-2-methyl-1,3-propanediol, 2-amino-2-ethyl-1,3-propanediol, and salts thereof. Further, in a case where the hydroxyl group is in the form of a salt, examples of the salt may include alkali metal salts such as a sodium salt and a potassium salt, ammonium salts, carbonates, and acetates.

Among these, an oxygen atom is preferably present only as a hydroxyl group from a viewpoint of further improving the effect of reducing residues. Further, from the viewpoint of further improving the effect of reducing residues, a compound having one or more and three or less amino groups and one or more and three or less hydroxyl groups is preferable, a compound having one or two primary or secondary amino groups (the total of the primary amino group and the secondary amino group is one or more and two or less) and one or two hydroxyl groups is more preferable, and a compound having one primary or secondary amino group and one hydroxyl group is particularly preferable.

To be specific, in one embodiment of the present invention, the component (B) (compound having an amino group and a hydroxyl group as the component (B)) contains at least one compound selected from the group consisting of 2-aminoethanol, 1-amino-2-propanol, 3-amino-1-propanol, diethanolamine, triethanolamine, 2-(2-aminoethylamino)ethanol, tris(hydroxymethyl)aminomethane, 2-(methylamino)ethanol, 2-(2-aminoethoxy)ethanol, 2-amino-2-methyl-1-propanol, 1-dimethylamino-2-propanol, 3-amino-1,2-propanediol, 2-amino-1,3-propanediol, 2-amino-2-methyl-1,3-propanediol, and 2-amino-2-ethyl-1,3-propanediol. In one embodiment of the present invention, the component (B) (compound having an amino group and a hydroxyl group as the component (B)) contains at least one compound selected from the group consisting of 2-aminoethanol, 3-amino-1-propanol, diethanolamine, 2-(2-aminoethylamino)ethanol, 2-(methylamino)ethanol, 2-(2-aminoethoxy)ethanol, 3-amino-1,2-propanediol, 2-amino-1,3-propanediol, and 2-amino-2-ethyl-1,3-propanediol. In one embodiment of the present invention, the component (B) (compound having an amino group and a hydroxyl group as the component (B)) contains at least one compound selected from the group consisting of 2-aminoethanol, 3-amino-1-propanol, 2-(2-aminoethylamino)ethanol, 2-(methylamino)ethanol, 3-amino-1,2-propanediol, and 2-amino-1,3-propanediol. In one embodiment of the present invention, the component (B) (compound having an amino group and a hydroxyl group as the component (B)) is at least one compound selected from the group consisting of 2-aminoethanol, 3-amino-1-propanol, 2-(2-aminoethylamino)ethanol, 2-(methylamino)ethanol, 3-amino-1,2-propanediol, and 2-amino-1,3-propanediol. In one embodiment of the present invention, the component (B) (compound having an amino group and a hydroxyl group as the component (B)) contains at least one compound selected from the group consisting of 3-amino-1-propanol and 2-(methylamino)ethanol. In one embodiment of the present invention, the component (B) (compound having an amino group and a hydroxyl group as the component (B)) is at least one compound selected from the group consisting of 3-amino-1-propanol and 2-(methylamino)ethanol.

In a case where the component (B) contains a compound represented by formula (1): H₂N[(CH₂)ₓNR¹]_{y}R², in the formula (1), R¹ is each independently a hydrogen atom or an alkyl group having 1 to 10 carbon atoms. Here, in a case where there are two or more [(CH₂)ₓNR¹] (y is 2 or more), R¹ in each [(CH₂)ₓNR¹] may be the same or different. Further, the alkyl group having 1 to 10 carbon atoms as R¹ may be linear, branched, or cyclic.

Specific examples of the linear alkyl group may include methyl group, ethyl group, n-propyl group, n-butyl group, n-pentyl group, n-hexyl group, n-heptyl group, n-octyl group, n-nonyl group, and n-decyl group.

Specific examples of the branched alkyl group may include isopropyl group, isobutyl group, sec-butyl group, tert-butyl group, isopentyl group, tert-pentyl group, neopentyl group, 1,2-dimethylpropyl group, isohexyl group, 1,3-dimethylbutyl group, 1-isopropylpropyl group, 1,2-dimethylbutyl group, 1,4-dimethylpentyl group, 3-ethylpentyl group, 2-methyl-1-isopropylpropyl group, 1-ethyl-3-methylbutyl group, 2-ethylhexyl group, 3-methyl-1-isopropylbutyl group, 2-methyl-1-isopropyl group, 1-tert-butyl-2-methylpropyl group, isodecyl group, and the like.

Specific examples of the cyclic (alicyclic) alkyl group may include cycloalkyl groups having 3 to 10 carbon atoms, such as a cyclopropyl group, a cyclobutyl group, a cyclopentyl group, and a cyclohexyl group.

Among these, the alkyl group as R¹ is preferably linear or branched, and more preferably linear.

For the alkyl group, the upper limit of the number of carbon atoms is preferably 8 or less, more preferably 6 or less, still more preferably 5 or less, and particularly preferably 3 or less, from a viewpoint of reducing residues (particularly organic residues). The lower limit of the number of carbon atoms is preferably 2 or more. Therefore, as an example, the number of carbon atoms of the alkyl group as R¹ and R² is preferably 1 or more and 8 or less, more preferably 1 or more and 6 or less, still more preferably 1 or more and 5 or less, particularly preferably 1 or more and 3 or less, and most preferably 1 or 2.

From the viewpoint of further improving the effect of reducing residues, R¹ is preferably a hydrogen atom or a linear or branched alkyl group having 1 to 5 carbon atoms, more preferably a hydrogen atom, methyl group, ethyl group, or n-propyl group, still more preferably a hydrogen atom, methyl group, or ethyl group, still more preferably a hydrogen atom or methyl group, and particularly preferably a hydrogen atom.

In the formula (1), R² is a hydrogen atom or an alkyl group having 1 to 10 carbon atoms. Examples of the alkyl group having 1 to 10 carbon atoms as R² are the same as those of R¹ described above.

From the viewpoint of further improving the effect of reducing residues, R² is preferably a hydrogen atom or a linear or branched alkyl group having 1 to 5 carbon atoms, more preferably a hydrogen atom, methyl group, ethyl group, or n-propyl group, still more preferably a hydrogen atom or methyl group, and particularly preferably a hydrogen atom.

In the formula (1), x is an integer of 1 or more and 10 or less. In a case where there are two or more [(CH₂)ₓNR¹] (y is 2 or more), x in each [(CH₂)ₓNR¹] may be the same or different. From the viewpoint of further improving the effect of reducing residues, x is preferably an integer of 1 or more and 8 or less, more preferably 1 or more and 5 or less, still more preferably 1 or more and 3 or less, particularly preferably 2 or 3, and most preferably 2.

In the formula (1), y is an integer of 1 or more and 8 or less. From the viewpoint of further improving the effect of reducing residues, y is preferably 1 or more and 7 or less, more preferably 1 or more and 5 or less, and particularly preferably 1 or more and 3 or less.

Examples of the compound represented by the formula (1) may include methylenediamine (in the formula (1), R¹, R²═H, x=1, and y=1), ethylenediamine (in the formula (1), R¹, R²═H, x=2, and y=1), diethylenetriamine (in the formula (1), R¹, R²═H, x=2, and y=2), triethylenetetramine (in the formula (1), R¹, R²═H, x=2, and y=3), tetraethylenepentamine (in the formula (1), R¹, R²═H, x=2, and y=4), pentaethylenehexamine (in the formula (1), R¹, R²═H, x=2, and y=5), hexaethyleneheptamine (in the formula (1), R¹, R²═H, x=2, and y=6), heptaethyleneoctamine (in the formula (1), R¹, R²═H, x=2, and y=7), propylenediamine (=diaminopropane) (in the formula (1), R¹, R²═H, x=3, and y=1), diaminobutane (in the formula (1), R¹, R²═H, x=4, and y=1), diaminopentane (in the formula (1), R¹, R²═H, x=5, and y=1), diaminohexane (in the formula (1), R¹, R²═H, x=6, and y=1), diaminoheptane (in the formula (1), R¹, R²═H, x=7, and y=1), diaminooctane (in the formula (1), R¹, R²═H, x=8, and y=1), diaminononane (in the formula (1), R¹, R²═H, x=9, and y=1), diaminodecane (in the formula (1), R¹, R²═H, x=10, y=1), dipropylenetriamine (in the formula (1), R¹, R²═H, x=3, and y=2), tripropylenetetramine (in the formula (1), R¹, R²═H, x=3, and y=3), and tetrapropylenepentamine (in the formula (1), R¹, R²═H, x=3, and y=4).

The component (B) preferably contains a compound of the formula (1) in which R¹ is a hydrogen atom (that is, both ends are primary amino groups or a combination of a primary amino group and a secondary amino group), and more preferably contains a compound of the formula (1) in which both R¹ and R² are hydrogen atoms (that is, both ends are primary amino groups), and it is particularly preferable to combine the component (B) with a nonionic polymer having a hydroxyl group (—OH) (the component (A)). The reason why the combination is preferable is considered as follows. The component (B) has a total of two or more primary amino groups and secondary amino groups. It is considered that the primary and secondary amino groups (particularly, the primary amino groups) can more easily interact with the hydroxyl group (—OH) contained in the component (A), and the hydroxyl group of the component (A) can be more easily adsorbed by the component (B). As a result, two components (A) can be more easily linked via the component (B), or the component (B) can be more easily crosslinked at two different portions of one component (A). Further, the component (A) can be more easily adsorbed on a polished object to be polished by the component (B) adsorbed on the polished object to be polished. Thus, the component (A) can form a thicker protective film (a water molecule film) more firmly on the surface of the polished object to be polished. Therefore, it is considered that wettability of the surface of the polished object to be polished can be further improved, and adhesion and re-adhesion of organic residue(s) can be effectively suppressed. It should be noted that the above mechanism is based on speculation, and the present invention is not limited to the above mechanism.

In one embodiment of the present invention, the component (B) contains at least one compound selected from the group consisting of 2-aminoethanol, 3-amino-1-propanol, diethanolamine, 2-(2-aminoethylamino)ethanol, 2-(methylamino)ethanol, 2-(2-aminoethoxy)ethanol, 3-amino-1,2-propanediol, 2-amino-1,3-propanediol, 2-amino-2-ethyl-1,3-propanediol, compounds represented by the formula (1), and hexamethylenetetramine. In one embodiment of the present invention, the component (B) contains at least one compound selected from the group consisting of 2-aminoethanol, 3-amino-1-propanol, 2-(2-aminoethylamino)ethanol, 2-(methylamino)ethanol, 3-amino-1,2-propanediol, 2-amino-1,3-propanediol, compounds represented by the formula (1), and hexamethylenetetramine. In one embodiment of the present invention, the component (B) is at least one compound selected from the group consisting of 2-aminoethanol, 3-amino-1-propanol, 2-(2-aminoethylamino)ethanol, 2-(methylamino)ethanol, 3-amino-1,2-propanediol, 2-amino-1,3-propanediol, compounds represented by the formula (1), and hexamethylenetetramine. In one embodiment of the present invention, the component (B) contains at least one compound selected from the group consisting of 3-amino-1-propanol, 2-(methylamino)ethanol, compounds represented by the formula (1), and hexamethylenetetramine. In one embodiment of the present invention, the component (B) contains at least one compound selected from the group consisting of compounds represented by the formula (1) and hexamethylenetetramine. In one embodiment of the present invention, the component (B) contains at least one compound selected from the group consisting of compounds represented by the formula (1) in which R¹ is a hydrogen atom, methyl group, ethyl group, or n-propyl group, R² is a hydrogen atom, methyl group, ethyl group, or n-propyl group, x is 1 or more and 5 or less, and y is 1 or more and 8 or less, and hexamethylenetetramine. In one embodiment of the present invention, the component (B) more preferably contains at least one compound selected from the group consisting of compounds represented by the formula (1) in which R¹ is a hydrogen atom or methyl group, R² is a hydrogen atom or methyl group, x is 1 or more and 3 or less, and y is 1 or more and 5 or less, and hexamethylenetetramine, or is at least one compound selected from the above group. In one embodiment of the present invention, the component (B) contains at least one compound selected from the group consisting of compounds represented by the formula (1) in which R¹ is a hydrogen atom, R² is a hydrogen atom, x is 2, and y is 1 or more and 3 or less, or is at least one compound selected from the above group. In one embodiment of the present invention, the component (B) is at least one compound selected from the group consisting of compounds represented by the formula (1) in which R¹ is a hydrogen atom, R² is a hydrogen atom, x is 2, and y is 1 or more and 3 or less.

The compound that can be used as the component (B) may be manufactured by synthesis or may be a commercially available product. The compounds as the component (B) can be used solely or in combination of two or more kinds thereof.

A content of the component (B) in the post-CMP cleaning composition is appropriately set depending on the type of the component (B) to be used and the desired effect. The content of the component (B) is preferably 0.01% by mass or more, more preferably 0.02% by mass or more, and particularly preferably 0.04% by mass or more, with the total mass of the post-CMP cleaning composition being 100% by mass (relative to the post-CMP cleaning composition). Further, the upper limit of the content of the component (B) in the post-CMP cleaning composition is preferably 0.3% by mass or less, more preferably 0.2% by mass or less, and particularly preferably 0.15% by mass or less, with the total mass of the post-CMP cleaning composition being 100% by mass (relative to the post-CMP cleaning composition). By setting such an upper limit, the component (B) itself is suppressed from becoming a residue, and residues can be efficiently removed. In one embodiment of the present invention, the content of the component (B) is 0.01% by mass or more and 0.3% by mass or less with the total mass of the post-CMP cleaning composition being 100% by mass (relative to the post-CMP cleaning composition). In one embodiment of the present invention, the content of the component (B) is 0.02% by mass or more and 0.2% by mass or less with the total mass of the post-CMP cleaning composition being 100% by mass (relative to the post-CMP cleaning composition). In one embodiment of the present invention, the content of the component (B) is 0.04% by mass or more and 0.15% by mass or less with the total mass of the post-CMP cleaning composition being 100% by mass (relative to the post-CMP cleaning composition). In a case where the post-CMP cleaning composition contains two or more kinds of component (B), the content of the component (B) is intended to be a total amount thereof.

In place of or in addition to the above, a concentration of the component (B) in the post-CMP cleaning composition may be appropriately set. In this case, an amount of the interactive groups present in the post-CMP cleaning composition, and therefore interaction with the component (A) can be appropriately adjusted, which is preferable. Specifically, the concentration of the component (B) in the post-CMP cleaning composition is preferably 1 mM or more, more preferably 3 mM or more, and particularly preferably more than 5 mM. Further, the upper limit of the concentration of the component (B) in the post-CMP cleaning composition is preferably 20 mM or less, more preferably 15 mM or less, particularly preferably 10 mM or less. By setting such an upper limit, the component (B) itself is suppressed from becoming a residue, and residues can be efficiently removed. In one embodiment of the present invention, the concentration of the component (B) is 1 mM or more and 20 mM or less. In one embodiment of the present invention, the concentration of the component (B) is 3 mM or more and 15 mM or less. In one embodiment of the present invention, the concentration of the component (B) is more than 5 mM and 10 mM or less. In a case where the post-CMP cleaning composition contains two or more kinds of components (B), the concentration of the component (B) is intended to be a total amount thereof.

In place of or in addition to the above, a mixing ratio of the component (B) and the component (A) in the post-chemical mechanical polishing cleaning composition may be appropriately set depending on the type of the component (B) and the component (A) to be used and the desired effect. The mixing ratio of the component (B) to the component (A) (component (B)/component (A) content ratio) (mass ratio) is preferably 0.3 or more, more preferably 0.4 or more, still more preferably 0.5 or more, and particularly preferably 0.6 or more. The mixing ratio of the component (B) to the component (A) (component (B)/component (A) content ratio) (mass ratio) is preferably 5 or less, more preferably 3 or less, still more preferably 2 or less, and particularly preferably less than 2. In one embodiment of the present invention, the mixing ratio of the component (B) to the component (A) (component (B)/component (A) content ratio) (mass ratio) is 0.3 or more and 5 or less. In one embodiment of the present invention, the mixing ratio of the component (B) to the component (A) (component (B)/component (A) content ratio) (mass ratio) is 0.4 or more and 3 or less. In one embodiment of the present invention, the mixing ratio of the component (B) to the component (A) (component (B)/component (A) content ratio) (mass ratio) is 0.5 or more and 2 or less. In one embodiment of the present invention, the mixing ratio of the component (B) to the component (A) (component (B)/component (A) content ratio) (mass ratio) is 0.6 or more and less than 2.

### <pH Adjusting Agent (Component (C))>

The post-chemical mechanical polishing cleaning composition according to the present invention essentially contains the components (A) and (B) as above, but preferably further contain a pH adjusting agent in addition to these components. To be specific, in a preferred embodiment of the present invention, the post-chemical mechanical polishing cleaning composition further contains the component (C):
Component (C): pH adjusting agent.

The pH adjusting agent is not particularly limited, and a known pH adjusting agent used in the field of a post-chemical mechanical polishing cleaning composition (post-CMP cleaning composition) can be used, and a known acid, base, salt thereof, or the like can be used. Examples of the pH adjusting agent may include organic acids such as carboxylic acids such as formic acid, acetic acid, glycolic acid, propionic acid, butyric acid, valeric acid, caproic acid, enanthic acid, caprylic acid, pelargonic acid, capric acid, lauric acid, myristic acid, palmitic acid, margaric acid, stearic acid, oleic acid, linoleic acid, linolenic acid, arachidonic acid, docosahexaenoic acid, eicosapentaenoic acid, lactic acid, malic acid, tartaric acid, citric acid, benzoic acid, phthalic acid, isophthalic acid, terephthalic acid, salicylic acid, gallic acid, mellitic acid, cinnamic acid, oxalic acid, malonic acid, succinic acid, glutaric acid, adipic acid, fumaric acid, maleic acid, aconitic acid, amino acids, and anthranilic acid, sulfonic acid (isethionic acid, camphor sulfonic acid and the like), and organic phosphonic acid (hydroxy ethylidene diphosphonic acid, diethylene triamine pentamethylene phosphonic acid, and the like); inorganic acids such as nitric acid, carbonic acid, hydrochloric acid, sulfuric acid, phosphoric acid, hypophosphorous acid, phosphorous acid, phosphonic acid, boric acid, hydrofluoric acid, orthophosphoric acid, pyrophosphoric acid, polyphosphoric acid, metaphosphoric acid, and hexametaphosphoric acid; hydroxides of alkali metals such as potassium hydroxide (KOH) and sodium hydroxide (NaOH); carbonates of alkali metals such as potassium carbonate (K₂CO₃) and sodium carbonate (Na₂CO₃); hydroxide of group 2 elements; ammonia (ammonium hydroxide); organic bases such as quaternary ammonium hydroxide compounds; and the like. As the pH adjusting agent, a synthetic product may be used, or a commercially available product may be used. Further, these pH adjusting agents can be used solely or in combination of two or more kinds thereof.

Among these, in a case where basicity of the component (B) is relatively low, and the desired pH of the post-CMP cleaning composition is relatively low, potassium hydroxide, sodium hydroxide, sodium carbonate, and ammonia are preferable, potassium hydroxide, sodium hydroxide, and ammonia are more preferable, and ammonia is particularly preferable. To be specific, in a preferred embodiment of the present invention, the pH adjusting agent is at least one selected from the group consisting of potassium hydroxide, sodium hydroxide, sodium carbonate, and ammonia. In a more preferred embodiment of the present invention, the pH adjusting agent is at least one selected from the group consisting of potassium hydroxide, sodium hydroxide, and ammonia. In a particularly preferred embodiment of the present invention, the pH adjusting agent is ammonia.

On the other hand, in a case where the basicity of the component (B) is relatively high, and the desired pH of the post-CMP cleaning composition is relatively high, acetic acid, sulfuric acid, nitric acid, hydrochloric acid, phosphoric acid, formic acid, propionic acid, butyric acid, oxalate acid, malonic acid, succinic acid, glutaric acid, adipic acid, maleic acid, malic acid, citric acid, glycolic acid, tartaric acid, lactic acid, and hydroxy ethylidene diphosphonic acid are preferable, and acetic acid is more preferable. To be specific, in a preferred embodiment of the present invention, the pH adjusting agent is at least one selected from the group consisting of acetic acid, sulfuric acid, nitric acid, hydrochloric acid, phosphoric acid, formic acid, propionic acid, butyric acid, oxalic acid, malonic acid, succinic acid, glutaric acid, adipic acid, maleic acid, malic acid, citric acid, glycolic acid, tartaric acid, lactic acid, and hydroxy ethylidene diphosphonic acid. In a more preferred embodiment of the present invention, the pH adjusting agent is acetic acid.

In one embodiment of the present invention, the pH adjusting agent is ammonia or acetic acid.

A content of the pH adjusting agent in the post-CMP cleaning composition may be appropriately selected so as to obtain a desired pH value of the post-CMP cleaning composition to be described in detail below.

### <pH of Post-Chemical Mechanical Polishing Cleaning Composition>

A pH of the post-chemical mechanical polishing cleaning composition (post-CMP cleaning composition) according to the present invention is more than 7.0 and 10.0 or less. When the pH of the post-CMP cleaning composition is 7.0 or less, residues remaining on a surface of a polished object to be polished cannot be sufficiently removed. From a viewpoint of further improving the effect by the present invention (in particular, removal of residues) and the like, the pH of the post-CMP cleaning composition is preferably 7.1 or more, more preferably 7.2 or more. The pH of the post-CMP cleaning composition is 10.0 or less. When the pH of the post-CMP cleaning composition exceeds 10.0, residues remaining on a surface of a polished object to be polished cannot be sufficiently removed. From the viewpoint of further improving the effect by the present invention (in particular, removal of residues) and the like, the pH of the post-CMP cleaning composition is preferably less than 10.0, more preferably 9.9 or less, still more preferably 9.5 or less, still more preferably 9.0 or less, still more preferably 8.5 or less, particularly preferably less than 8.0, and most preferably 7.5 or less. To be specific, in one embodiment of the present invention, the pH of the post-CMP cleaning composition is 7.1 or more and less than 10.0. In one embodiment of the present invention, the pH of the post-CMP cleaning composition is 7.1 or more and 9.9 or less. In one embodiment of the present invention, the pH of the post-CMP cleaning composition is 7.2 or more and 9.5 or less. In one embodiment of the present invention, the pH of the post-CMP cleaning composition is 7.2 or more and 9.0 or less. In one embodiment of the present invention, the pH of the post-CMP cleaning composition is 7.2 or more and 8.5 or less. In one embodiment of the present invention, the pH of the post-CMP cleaning composition is 7.2 or more and less than 8.0. In one embodiment of the present invention, the pH of the post-CMP cleaning composition is 7.2 or more and 7.5 or less. As the pH of the post-CMP cleaning composition, a value measured by the method described in Examples is adopted.

### <Solvent>

The post-chemical mechanical polishing cleaning composition according to the present invention preferably contains a solvent. The solvent serves to disperse or dissolve each component. The solvent preferably contains water, and is more preferably only water. Further, the solvent may be a mixed solvent of water and an organic solvent for dispersing or dissolving each component. In this case, examples of the organic solvent to be used may include acetone, acetonitrile, ethanol, methanol, isopropanol, glycerin, ethylene glycol, propylene glycol, triethanolamine, and the like, which are an organic solvent miscible with water. Further, these organic solvents may be used without being mixed with water. For example, the organic solvent may be used to disperse or dissolve each component prior to being mixed with water. These organic solvents can be used solely or in combination of two or more kinds thereof.

Preferably, water is as residue-free as possible from a viewpoint of preventing contamination of a polished object to be polished and inhibition of an action of other components. For example, water having a total content of transition metal ions of 100 ppb or less is preferable. Here, the purity of water can be increased by, for example, operations such as removal of residue ions using an ion exchange resin, removal of foreign matters by a filter, and distillation. Specifically, for example, it is preferable to use deionized water (ion-exchanged water), pure water, ultrapure water, distilled water, or the like.

### <Antifungal Agent (Antiseptic Agent)>

The post-chemical mechanical polishing cleaning composition (post-CMP cleaning composition) according to the present invention may further contain an antifungal agent (antiseptic agent). The post-CMP cleaning composition according to the present invention contains a nonionic polymer and is alkaline. For this reason, the post-CMP cleaning composition according to the present invention preferably contains an antifungal agent (antiseptic agent).

The antifungal agent (antiseptic agent) that can be used in a case where the post-CMP cleaning composition according to the present invention contains an antifungal agent (antiseptic agent) is not particularly limited, and can be appropriately selected depending on the type of the nonionic polymer (component (A)). Specific examples thereof may include isothiazoline-based antiseptic agent such as 2-methyl-4-isothiazoline-3-one, 5-chloro-2-methyl-4-isothiazoline-3-one and 1,2-benzisothiazole-3(2H)-one (BIT), phenoxyethanol, and the like. Among these, an isothiazoline-based antiseptic agent is preferably used.

The antifungal agent (antiseptic agent) may be used solely or in combination of two or more kinds thereof.

The antifungal agent (antiseptic agent) may be manufactured by synthesis or may be a commercially available product. Examples of commercially available products may include San-ai bac series such as San-ai bac R-30 (manufactured by SAN-AI OBBLI CO., LTD., an isothiazoline-based compound), KORDEK MLX (KORDEK (trademark) MLX) (Nutrition & Biosciences Japan K.K.), and the like.

In a case where the post-CMP cleaning composition contains an antifungal agent (antiseptic agent), the lower limit of a content (concentration) of the antifungal agent (antiseptic agent) is not particularly limited, but is preferably 0.0001% by mass or more, more preferably 0.001% by mass or more. Further, the upper limit of the content (concentration) of the antifungal agent (antiseptic agent) is not particularly limited, but is preferably 1% by mass or less, and more preferably 0.1% by mass or less. To be specific, the content (concentration) of the antifungal agent (antiseptic agent) in the post-CMP cleaning composition is preferably 0.0001% by mass or more and 1% by mass or less, and more preferably 0.001% by mass or more and 0.1% by mass or less. Such a range is sufficient to inactivate or destroy a microorganism(s). In a case where the post-CMP cleaning composition contains two or more kinds of antifungal agents (antiseptic agents), the content is intended to be a total amount thereof.

### <Surfactant>

The post-chemical mechanical polishing cleaning composition (post-CMP cleaning composition) according to the present invention may further contain a surfactant. The type of surfactant is not particularly limited, and may be any of nonionic, anionic, cationic, and amphoteric surfactants.

Examples of the nonionic surfactant may include compounds other than the component (A). Examples thereof may include alkyl ether type such as polyoxyethylene lauryl ether and polyoxyethylene oleyl ether; alkylphenyl ether type such as polyoxyethylene octyl phenyl ether; alkyl ester type such as polyoxyethylene laurate; alkylamine type such as polyoxyethylene lauryl amino ether; alkylamide type such as polyoxyethylene lauric acid amide; polypropylene glycol ether type such as polyoxyethylene polyoxypropylene ether; alkanolamide type such as oleic acid diethanolamide; allyl phenyl ether type such as polyoxyalkylene allyl phenyl ether; and the like. In addition, propylene glycol, diethylene glycol, monoethanolamine, alcohol ethoxylate, alkylphenol ethoxylate, tertiary acetylene glycol, alkanolamide, and the like can also be used as the nonionic surfactant. Since the component (A) can serve as a nonionic surfactant, it is not necessary to add a separate nonionic surfactant.

Examples of the anionic surfactant may include carboxylic acid type such as sodium myristate, sodium palmitate, sodium stearate, sodium laurate, and potassium laurate; sulfuric acid ester type such as sodium octyl sulfate; phosphoric acid ester type such as lauryl phosphate and sodium lauryl phosphate; sulfonic acid type such as sodium dioctyl sulfosuccinate and sodium dodecylbenzenesulfonate; and the like.

Examples of the cationic surfactant may include amines such as laurylamine hydrochloride, and the like.

Examples of the amphoteric surfactant may include lecithin, alkylamine oxide, alkyl betaine such as N-alkyl-N,N-dimethylammonium betaine, sulfobetaine, and the like.

The surfactant may be used solely or in combination of two or more kinds thereof. Further, as the surfactant, a commercially available product may be used, or a synthetic product may be used.

In a case where the post-CMP cleaning composition contains a surfactant, the lower limit of a content of the surfactant is preferably 0.01% by mass or more, more preferably 0.05% by mass or more, with the total mass of the post-CMP cleaning composition being 100% by mass. Further, the upper limit of the content of the surfactant in the post-CMP cleaning composition is preferably 5% by mass or less, more preferably 1% by mass or less, with the total mass of the post-CMP cleaning composition being 100% by mass. In a case where the post-CMP cleaning composition contains two or more kinds of surfactants, the content of the surfactants is intended to be a total amount thereof.

From a viewpoint of further improving the effect of removing residues (foreign matters), it is preferable that the post-CMP cleaning composition according to the present invention does not substantially contain a surfactant (an anionic surfactant and an amphoteric surfactant). As used herein, the phrase “does not substantially contain a surfactant” refers to a case where a content of the surfactant (total content of the anionic surfactant and the amphoteric surfactant) is less than 0.01% by mass (preferably less than 0.0005% by mass) relative to the entire post-CMP cleaning composition. To be specific, in one embodiment of the present invention, the content of the surfactant is less than 0.01% by mass (preferably less than 0.0005% by mass) (lower limit: 0% by mass), with the total mass of the post-CMP cleaning composition being 100% by mass (relative to the post-CMP cleaning composition). From a viewpoint of further inhibiting a cause of foreign matters (residues), the post-CMP cleaning composition is free of an anionic surfactant and an amphoteric surfactant (the total content of the anionic surfactant and the amphoteric surfactant=0% by mass).

### <Chelating Agent>

The post-chemical mechanical polishing cleaning composition (post-CMP cleaning composition) according to the present invention may further comprise a chelating agent. Examples of the chelating agent may include an aminocarboxylic acid-based chelating agent and an organic phosphonic acid-based chelating agent. Examples of the aminocarboxylic acid-based chelating agent may include ethylenediaminetetraacetic acid, sodium ethylenediaminetetraacetic acid, nitrilotriacetic acid, sodium nitrilotriacetic acid, ammonium nitrilotriacetic acid, diethylenetriaminepentaacetic acid, sodium diethylenetriaminepentaacetic acid, triethylenetetramine hexaacetic acid, and sodium triethylenetetramine hexaacetic acid. Examples of the organic phosphonic acid-based chelating agent may include 2-aminoethylphosphonic acid, 1-hydroxyethylidene-1,1-diphosphonic acid, aminotri(methylenephosphonic acid), ethylenediaminetetrakis(methylenephosphonic acid) (EDTPO), diethylenetriaminepenta(methylenephosphonic acid), ethane-1,1-diphosphonic acid, ethane-1,1,2-triphosphonic acid, and ethane-1-hydroxy-1,1-diphosphonic acid, ethane-1-hydroxy-1,1,2-triphosphonic acid, ethane-1,2-dicarboxy-1,2-diphosphonic acid, methanhydroxyphosphonic acid, 2-phosphonobutane-1,2-dicarboxylic acid, 1-phosphonobutane-2,3,4-tricarboxylic acid, and α-methylphosphonosuccinic acid. Among these, an organic phosphonic acid-based chelating agent is more preferable. Among these, ethylenediaminetetrakis(methylenephosphonic acid), diethylenetriaminepenta(methylenephosphonic acid), and diethylenetriaminepentaacetic acid are preferable. Particularly preferred chelating agents include ethylenediaminetetrakis(methylenephosphonic acid) and diethylenetriaminepenta(methylenephosphonic acid).

The chelating agent may be used solely or in combination of two or more kinds thereof. Further, as the chelating agent, a commercially available product may be used, or a synthetic product may be used.

In a case where the post-CMP cleaning composition contains a chelating agent, the lower limit of a content of the chelating agent is preferably 0.0001% by mass or more, more preferably 0.001% by mass or more, and still more preferably 0.002% by mass or more, with the total mass of the post-CMP cleaning composition being 100% by mass. The upper limit of the content of the chelating agent is preferably 1% by mass or less, more preferably 0.5% by mass or less, still more preferably 0.3% by mass or less, and particularly preferably 0.15% by mass or less. In a case where the post-CMP cleaning composition contains two or more kinds of chelating agents, the content of the chelating agents is intended to be a total amount thereof.

From the viewpoint of further improving the effect of removing residues (foreign matters), the post-CMP cleaning composition according to the present invention preferably does not substantially contain a chelating agent. As used herein, the phrase “does not substantially contain a chelating agent” refers to a case where a content of the chelating agent (a total amount thereof in a case where a plurality of chelating agents are contained) is less than 0.01% by mass (preferably less than 0.0005% by mass) relative to the entire post-CMP cleaning composition. To be specific, in one embodiment of the present invention, the content of the chelating agent is less than 0.01% by mass (preferably less than 0.0005% by mass) (lower limit: 0% by mass), with the total mass of the post-CMP cleaning composition being 100% by mass (relative to the post-CMP cleaning composition). From the viewpoint of further inhibiting a cause of foreign matters (residues), the post-CMP cleaning composition is free of a chelating agent (the content of the chelating agent=0% by mass).

### <Another Additive(s)>

The post-chemical mechanical polishing cleaning composition (post-CMP cleaning composition) according to one embodiment of the present invention may contain another additive(s) in an arbitrary ratio as necessary so long as the effect of the present invention is not inhibited. However, since components other than essential components of the post-CMP cleaning composition according to one embodiment of the present invention may cause foreign matters (residues), it is desirable that the components are added as little as possible. Therefore, an addition amount of another additive(s) is preferably as small as possible. Examples of the another additive (s) may include a dissolved gas, a reducing agent, an oxidizing agent, and the like.

In order to further improve the effect of removing residues (foreign matters), it is preferable that the post-chemical mechanical polishing cleaning composition (post-CMP cleaning composition) according to the present invention does not substantially contain abrasive grains. As used herein, the phrase “does not substantially contain abrasive grains” refers to a case where a content of the abrasive grains relative to the entire post-CMP cleaning composition is less than 0.01% by mass. To be specific, in one embodiment of the present invention, the content of the abrasive grains is less than 0.01% by mass (lower limit: 0% by mass), with the total mass of the post-CMP cleaning composition being 100% by mass (relative to the post-CMP cleaning composition). From the viewpoint of further inhibiting the cause of foreign matters (residues), the post-CMP cleaning composition is free of abrasive grains (the content=0% by mass).

In place of or in addition to the above, in order to further improve the effect of removing residues (foreign matters), the post-chemical mechanical polishing cleaning composition (post-CMP cleaning composition) according to the present invention preferably does not substantially contain particles having a particle size of 0.1 to 0.3 μm. As used herein, the phrase “does not substantially contain particles having a particle size of 0.1 to 0.3 μm” refers to a case where the number of particles having a particle size of 0.1 to 0.3 μm present in the post-CMP cleaning composition is less than 30 (preferably less than 10, more preferably less than 5). To be specific, in one embodiment of the present invention, the number of particles having a particle size of 0.1 to 0.3 μm present in the post-CMP cleaning composition is less than 30 (preferably less than 10, more preferably less than 5). From the viewpoint of further inhibiting the cause of foreign matters (residues), the post-CMP cleaning composition is free of particles having a particle size of 0.1 to 0.3 μm (the number of particles=0).

In place of or in addition to the above, in order to further improve the effect of removing residues (foreign matters), it is preferable that the post-chemical mechanical polishing cleaning composition (post-CMP cleaning composition) according to the present invention does not substantially contain a buffer, particularly a buffer (ammonium monocarboxylate) represented by formula: A-COO⁻NH₄⁺ (wherein A is an alkyl group having 1 to 10 carbon atoms or a phenyl group). As used herein, the phrase “does not substantially contain a buffer” refers to a case where the content of the buffer relative to the entire post-CMP cleaning composition is less than 0.01% by mass. To be specific, in one embodiment of the present invention, the content of the buffer is less than 0.01% by mass (lower limit: 0% by mass) with the total mass of the post-CMP cleaning composition being 100% by mass (relative to the post-CMP cleaning composition). In one embodiment of the present invention, the post-CMP cleaning composition is free of a buffer (the content=0% by mass). In one embodiment of the present invention, the post-CMP cleaning composition is free of a buffer (ammonium monocarboxylate) represented by the formula: A-COO⁻NH₄⁺ (the content=0% by mass).

In one embodiment of the present invention, the post-chemical mechanical polishing cleaning composition (post-CMP cleaning composition) is substantially composed of a nonionic polymer (component (A)), at least one compound selected from the group consisting of a compound having an amino group and a hydroxyl group, a compound represented by formula (1): H₂N[(CH₂)ₓNR¹]_{y}R², and hexamethylenetetramine (component (B)), and at least one selected from the group consisting of a pH adjusting agent (component (C)), an antifungal agent (antiseptic agent), water, and an organic solvent. In one embodiment of the present invention, the post-CMP cleaning composition is substantially composed of a nonionic polymer (component (A)), at least one compound selected from the group consisting of a compound having an amino group and a hydroxyl group, a compound represented by formula (1): H₂N[(CH₂)ₓNR¹]_{y}R², and hexamethylenetetramine (component (B)), and at least one selected from the group consisting of a pH adjusting agent (component (C)), an isothiazoline-based antiseptic agent, and water. In one embodiment of the present invention, the post-CMP cleaning composition is substantially composed of a nonionic polymer (component (A)), at least one compound selected from the group consisting of a compound represented by formula (1): H₂N[(CH₂)ₓNR¹]_{y}R² and hexamethylenetetramine (component (B)), a pH adjusting agent (component (C)), an isothiazoline-based antiseptic agent and water. In one embodiment of the present invention, the post-CMP cleaning composition is substantially composed of a nonionic polymer (component (A)), at least one compound selected from the group consisting of a compound represented by formula (1): H₂N[(CH₂)ₓNR¹]_{y}R² (wherein R¹ is a hydrogen atom or a methyl group, R² is a hydrogen atom or a methyl group, x is 1 or more and 3 or less, and y is 1 or more and 5 or less) and hexamethylenetetramine (component (B)), a pH adjusting agent (component (C)), an isothiazoline-based antiseptic agent and water. In one embodiment of the present invention, the post-CMP cleaning composition is substantially composed of a nonionic polymer (component (A)), at least one compound selected from the group consisting of a compound represented by formula (1): H₂N[(CH₂)ₓNR¹]_{y}R² (wherein R¹ is a hydrogen atom, R² is a hydrogen atom, x is 2, and y is 1 or more and 3 or less) and hexamethylenetetramine (component (B)), a pH adjusting agent (component (C)), an isothiazoline-based antiseptic agent and water. In the embodiments, the phrase “the post-CMP cleaning composition is substantially composed of X” means that the total content of X is more than 99% by mass (upper limit: 100% by mass) with the total mass of the post-CMP cleaning composition being 100% by mass (relative to the post-CMP cleaning composition). Preferably, the post-CMP cleaning composition is composed of X (the above total content=100% by mass).

To be specific, in a preferred embodiment of the present invention, the post-chemical mechanical polishing cleaning composition (post-CMP cleaning composition) is composed of a nonionic polymer (component (A)), at least one compound selected from the group consisting of a compound having an amino group and a hydroxyl group, a compound represented by formula (1): H₂N[(CH₂)ₓNR¹]_{y}R², and hexamethylenetetramine (component (B)), and at least one selected from the group consisting of a pH adjusting agent (component (C)), an antifungal agent (antiseptic agent), water, and an organic solvent (total content thereof=100% by mass). In a preferred embodiment of the present invention, the post-CMP cleaning composition is composed of a nonionic polymer (component (A)), at least one compound selected from the group consisting of a compound having an amino group and a hydroxyl group, a compound represented by formula (1): H₂N[(CH₂)ₓNR¹]_{y}R², and hexamethylenetetramine (component (B)), and at least one selected from the group consisting of a pH adjusting agent (component (C)), an isothiazoline-based antiseptic agent, and water (total content thereof=100% by mass). In a preferred embodiment of the present invention, the post-CMP cleaning composition is composed of a nonionic polymer (component (A)), at least one compound selected from the group consisting of a compound represented by formula (1): H₂N[(CH₂)ₓNR¹]_{y}R² and hexamethylenetetramine (component (B)), a pH adjusting agent (component (C)), an isothiazoline-based antiseptic agent and water (total content thereof=100% by mass) In a preferred embodiment of the present invention, the post-CMP cleaning composition is composed of a nonionic polymer (component (A)), at least one compound selected from the group consisting of a compound represented by formula (1): H₂N[(CH₂)ₓNR¹]_{y}R² (wherein R¹ is a hydrogen atom or a methyl group, R² is a hydrogen atom or a methyl group, x is 1 or more and 3 or less, and y is 1 or more and 5 or less) and hexamethylenetetramine (component (B)), a pH adjusting agent (component (C)), an isothiazoline-based antiseptic agent and water (total content thereof=100% by mass). In a preferred embodiment of the present invention, the post-CMP cleaning composition is composed of a nonionic polymer (component (A)), at least one compound selected from the group consisting of a compound represented by formula (1): H₂N[(CH₂)ₓNR¹]_{y}R² (wherein R¹ is a hydrogen atom, R² is a hydrogen atom, x is 2, and y is 1 or more and 3 or less) and hexamethylenetetramine (component (B)), a pH adjusting agent (component (C)), an isothiazoline-based antiseptic agent and water (total content thereof=100% by mass).

Electrical conductivity (EC) of the post-chemical mechanical polishing cleaning composition of the present invention is preferably 0.1 mS/cm or more and less than 1.5 mS/cm, and more preferably 0.2 mS/cm or more and less than 1.3 mS/cm. When the electrical conductivity of the post-chemical mechanical polishing cleaning composition is in the above range, the desired effect of the present invention can be efficiently exhibited. The electrical conductivity (EC) of the post-chemical mechanical polishing cleaning composition is measured according to the method described in Examples.

### <Method for Producing Post-Chemical Mechanical Polishing Cleaning Composition>

A method for producing the post-chemical mechanical polishing cleaning composition according to the present invention is not particularly limited. The post-chemical mechanical polishing cleaning composition can be obtained, for example, by stirring and mixing a nonionic polymer (the component (A)), at least one compound (the component (B)) selected from the group consisting of a compound having an amino group and a hydroxyl group, a compound represented by formula (1): H₂N[(CH₂)ₓNR¹]_{y}R², and hexamethylenetetramine, and another additive(s) added as necessary. Details of each component are as described above. A temperature at which each component is mixed is not particularly limited, but is preferably 10° C. or more and 40° C. or less. Heating may be performed in order to increase a dissolution rate. Further, a mixing time is also not particularly limited.

### [Post-Chemical Mechanical Polishing and Cleaning Treatment (Surface Treatment) Method]

According to the post-CMP cleaning composition according to the present invention, residues remaining on a surface of a polished object to be polished can be sufficiently removed (the number of residues remaining on a surface of a polished object to be polished after CMP can be effectively reduced). Further, surface roughness of a polished object to be polished (in particular, a polished substrate having a silicon-silicon bond) can be reduced. Therefore, the present invention is to provide a post-chemical mechanical polishing and cleaning treatment method including subjecting a polished object to be polished to post-chemical mechanical polishing and cleaning treatment (surface treatment) using the post-CMP cleaning composition according to the present invention. Here, the polished object to be polished may contain a material containing a silicon-silicon bond (silicon material). To be specific, the present invention is to provide a post-chemical mechanical polishing and cleaning treatment method including subjecting a polished object to be polished having a silicon-silicon bond to post-chemical mechanical polishing and cleaning treatment (surface treatment) using the post-chemical mechanical polishing cleaning composition according to the present invention to reduce residues on a surface of the polished object to be polished. In the present description, the “post-chemical mechanical polishing and cleaning treatment method” refers to a method for reducing residues on a surface of a polished object to be polished, and is a method for performing cleaning in a broad sense. In the present description, the “post-chemical mechanical polishing and cleaning treatment” is also simply referred to as “a post-CMP cleaning treatment”.

According to the post-CMP cleaning treatment method according to the present invention, residues remaining on a surface of a polished object to be polished can be sufficiently removed. To be specific, the present invention is to provide a method of reducing residues on a surface of a polished object to be polished, including subjecting the polished object to be polished that contains a material having a silicon-silicon bond (silicon material) to post-CMP cleaning treatment using the post-chemical mechanical polishing cleaning composition according to the present invention.

The post-CMP cleaning treatment method according to the present invention can be performed by a method of bringing the post-CMP cleaning composition according to the present invention into direct contact with a polished object to be polished.

Examples of the post-CMP cleaning treatment method may mainly include (I) a method by rinse polishing treatment and (II) a method by cleaning treatment. To be specific, in one embodiment of the present invention, the post-chemical mechanical polishing and cleaning treatment method is a rinse polishing treatment method or a cleaning treatment method (the post-chemical mechanical polishing and cleaning treatment is performed by rinse polishing treatment or cleaning treatment). The rinse polishing treatment and the cleaning treatment are performed in order to remove foreign matters (abrasive grain (particle) residue(s), organic residue(s) such as polymers and pad debris, metal contaminant(s), and the like) on a surface of a polished object to be polished and obtain a clean surface. Hereinafter, the (I) and (II) methods will be described.

### (I) Rinse Polishing Treatment

The post-chemical mechanical polishing cleaning composition (post-CMP cleaning composition) according to the present invention can be suitably used in the rinse polishing treatment. To be specific, the post-CMP cleaning composition according to the present invention can be preferably used as a rinse polishing composition. After an object to be polished has been subjected to final polishing (finish polishing) to obtain a polished object to be polished, the rinse polishing treatment is performed on a polishing table (platen) to which a polishing pad is attached, for the purpose of removing foreign matters on the surface of the polished object to be polished. At this time, the rinse polishing treatment is performed by contacting the post-CMP cleaning composition according to the present invention directly with the polished object to be polished. As a result, foreign matters on the surface of the polished object to be polished can be removed by frictional force (physical action) by the polishing pad and chemical action by the post-CMP cleaning composition. Among the foreign matters, particularly, abrasive grain (particle) residues and organic residues can be easily removed by physical action. Therefore, in the rinse polishing treatment, abrasive grain (particle) residues and organic residues can be effectively removed by using friction with the polishing pad on the polishing table (platen). Here, in the post-CMP cleaning treatment using the post-CMP cleaning composition according to the present invention, a surface of a polished object to be polished can be etched by frictional force (physical action) by the polishing pad and chemical action by the post-CMP cleaning composition. Then, since abrasive grain residues and organic residues are removed together with this etching, efficiency of reducing these residues can be further improved. Further, at this time, since a surface of a polished object to be polished is uniformly etched, surface roughness can also be reduced.

To be specific, in the present description, the rinse polishing treatment, the rinse polishing method, and the rinse polishing step are respectively referred to a treatment, a method, and a step for reducing residues on a surface of an object to be subjected to post-CMP cleaning treatment using a polishing pad.

Specifically, the rinse polishing treatment can be performed by placing a surface of a polished object to be polished after the polishing step on a polishing table (platen) of a polishing apparatus, contacting a polishing pad with the polished object to be polished, and relatively sliding the polished object to be polished and the polishing pad while supplying the post CMP cleaning composition to the contact portion.

As the polishing apparatus, it is possible to use a general polishing apparatus that is equipped with a holder for holding an object to be polished, a motor capable of changing a rotation speed, and the like, and has a polishing table to which a polishing pad (polishing cloth) can be attached.

The rinse polishing treatment can be performed using either a single-side polishing apparatus or a double-side polishing apparatus. Further, the polishing apparatus is preferably equipped with a discharge nozzle of the post-CMP cleaning composition as well as a discharge nozzle of the polishing composition. Operating conditions of the polishing apparatus during the rinse polishing treatment are not particularly limited, and can be appropriately set by those skilled in the art.

As the polishing pad, a general nonwoven fabric, polyurethane, porous fluororesin, and the like can be used without any particular limitation. The polishing pad is preferably subjected to grooving so that the post-CMP cleaning composition is accumulated.

There are no particular limitations on rinse polishing conditions. For example, a rotation speed of a polishing table and a rotation speed of a head (carrier) are preferably 10 rpm (0.17 s⁻¹) or more and 100 rpm (1.67 s⁻¹) or less. A pressure (polishing pressure) applied to a polished object to be polished is preferably 0.5 psi (3.4 kPa) or more and 10 psi (68.9 kPa) or less. A method of supplying the post-CMP cleaning composition to a polishing pad is also not particularly limited. For example, a method of continuously supplying the post-CMP cleaning composition with a pump or the like (continuous pouring and flowing) can be employed. There is no limit to a supply amount, but it is preferable that a surface of a polishing pad is always covered with the post-CMP cleaning composition. The supply amount is preferably 10 mL/min or more and 5000 mL/min or less. A rinse polishing time is also not particularly limited, but is preferably 5 seconds or more and 180 seconds or less.

After the rinse polishing treatment with the post-CMP cleaning composition according to the present invention, the polished object to be polished (object to be subjected to surface treatment) is preferably pulled up and taken out while applying the post-CMP cleaning composition according to the present invention.

### (II) Cleaning Treatment

The post-chemical mechanical polishing cleaning composition (post-CMP cleaning composition) according to the present invention may be used in cleaning treatment. To be specific, the post-CMP cleaning composition according to the present invention can be preferably used as a cleaning composition. The cleaning treatment is preferably performed for the purpose of removing foreign matters on a surface of a polished object to be polished (object to be cleaned) after the final polishing (finish polishing) is performed on an object to be polished, the rinse polishing treatment is performed, or after another rinse polishing treatment using a rinse polishing composition other than the post-CMP cleaning composition according to the present invention is performed to obtain a polished object to be polished (object to be cleaned). The cleaning treatment and the rinse polishing treatment are divided depending on a place where the treatments are performed. The cleaning treatment is post-CMP cleaning treatment (surface treatment) performed at a place other than on a polishing table (platen), and is preferably post-CMP cleaning treatment (surface treatment) performed after a polished object to be polished is removed from a polishing table (platen). Also in the cleaning treatment, the post-CMP cleaning composition according to the present invention can be directly contacted with a polished object to be polished to remove foreign matters on a surface of the object.

Examples of the method of performing the cleaning treatment may include (i) a method which comprises contacting a cleaning brush with one surface or both surfaces of a polished object to be polished while holding the polished object to be polished, and rubbing the surface of the object to be cleaned with the cleaning brush while supplying the post CMP cleaning composition to the contact portion, (ii) a method which comprises immersing a polished object to be polished in the post CMP cleaning composition, and performing ultrasonic treatment or stirring (dip type), and the like. In such a method, foreign matters on a surface of the polished object to be polished can be removed by frictional force by the cleaning brush or mechanical force generated by ultrasonic treatment or stirring, and chemical action by the post-CMP cleaning composition.

In the method (i), the method of contacting the post-CMP cleaning composition with a polished object to be polished is not particularly limited. Examples thereof may include a spin type in which the polished object to be polished is rotated at a high speed while the post-CMP cleaning composition is continuously poured and flowed from a nozzle onto the polished object to be polished, a spray type in which the post-CMP cleaning composition is sprayed onto the polished object to be polished to clean the polished object to be polished, and the like.

From a viewpoint that more efficient decontamination can be performed in a short time, it is preferable to adopt a spin type or a spray type for the cleaning treatment, and it is more preferable to adopt a spin type.

Examples of an apparatus for performing such cleaning treatment may include a batch-type cleaning apparatus that simultaneously performs post-CMP cleaning treatment (surface treatment) on a plurality of polished objects to be polished housed in a cassette, a single-wafer type cleaning apparatus that attaches one polished object to be polished to a holder and performs post-CMP cleaning treatment (surface treatment), and the like. From a viewpoint of shortening cleaning time and the like, a method using a single-wafer type cleaning apparatus is preferable.

Furthermore, examples of an apparatus for performing the cleaning treatment may include a polishing apparatus that includes a cleaning facility for removing a polished object to be polished from a polishing table (platen) and then rubbing the object with a cleaning brush. By using such a polishing apparatus, the cleaning treatment of the polished object to be polished can be more efficiently performed.

As such a polishing apparatus, a general polishing apparatus that includes a holder for holding a polished object to be polished, a motor capable of changing a rotation speed, a cleaning brush, and the like can be used. As the polishing apparatus, either a single-side polishing apparatus or a double-side polishing apparatus may be used. In a case where the rinse polishing step is performed after a CMP step, it is more efficient and preferable to perform the cleaning treatment using the same apparatus as the polishing apparatus used in the rinse polishing step.

The cleaning brush is not particularly limited, but is preferably a resin brush. A material of the resin brush is not particularly limited, but PVA (polyvinyl alcohol) is preferable. The cleaning brush is more preferably a PVA sponge.

There is no particular limitation on cleaning conditions, and the condition can be appropriately set depending on a type of an object to be subjected to surface treatment (polished object to be polished) and a type and amount of residues to be removed. For example, a rotation speed of a cleaning brush is preferably 10 rpm (0.17 s⁻¹) or more and 200 rpm (3.33 s⁻¹) or less. A rotation speed of an object to be cleaned is preferably 10 rpm (0.17 s⁻¹) or more and 100 rpm (1.67 s⁻¹) or less. A method of supplying the post-CMP cleaning composition to a cleaning brush is also not particularly limited. For example, a method of continuously supplying the post-CMP cleaning composition with a pump or the like (continuous pouring and flowing) can be employed. There is no limit to a supply amount, but it is preferable that the surfaces of a cleaning brush and an object to be cleaned are always covered with the post-CMP cleaning composition, and the supply amount is preferably 10 mL/min or more and 5000 mL/min or less. A cleaning time is also not particularly limited, but is preferably 5 seconds or more and 180 seconds or less in a step using the post-CMP cleaning composition according to one embodiment of the present invention. Within such a range, foreign matters can be more effectively removed.

A temperature of the post-CMP cleaning composition during cleaning is not particularly limited, and may be usually room temperature, but may be heated to about 40° C. or more and 70° C. or less as long as the performance is not impaired.

In the method (ii), conditions in a cleaning method by immersion are not particularly limited, and a known method can be used.

Cleaning with water may be performed before performing the post-CMP cleaning treatment (surface treatment) by the method (I) or (II).

### (Post-Cleaning Treatment)

As a post-CMP cleaning treatment (surface treatment) method, it is preferable to further clean a polished object to be polished after the post-CMP cleaning treatment of (I) or (II) using the post-CMP cleaning composition according to the present invention. In the present description, the cleaning treatment refers to post-cleaning treatment. The post-cleaning treatment is not particularly limited, and examples thereof may include a method of simply flowing water through an object to be subjected to surface treatment, a method of simply immersing an object to be subjected to surface treatment in water, and the like. Further, similarly to the post-CMP cleaning treatment by the method (II) as described above, examples thereof may include a method in which a cleaning brush is contacted with one side or both sides of an object to be subjected to surface treatment in a state where the object to be subjected to surface treatment is held, and a surface of an object to be subjected to surface treatment is rubbed with a cleaning brush while water or an aqueous solution (for example, NH₃ aqueous solution) is supplied to the contact portion or water and an aqueous solution (for example, NH₃ aqueous solution) is supplied in any order (after water is supplied, an aqueous solution is supplied, or after an aqueous solution is supplied, water is supplied) (brush cleaning), a method in which an object to be subjected to surface treatment is immersed in water, and ultrasonic treatment or stirring is performed (dip type), and the like. Among these methods, a method in which a cleaning brush is contacted with one side or both sides of an object to be subjected to surface treatment in a state where the object to be subjected to surface treatment is held, and a surface of an object to be subjected to surface treatment is rubbed with a cleaning brush while water or an aqueous solution (for example, NH₃ aqueous solution) is supplied to the contact portion or water and an aqueous solution (for example, NH₃ aqueous solution) is supplied in any order (after water is supplied, an aqueous solution is supplied, or after an aqueous solution is supplied, water is supplied) (brush cleaning) is preferable. The description of the post-CMP cleaning process in (II) described above can be referred to as the apparatus and conditions for the post-cleaning treatment. Here, it is particularly preferable to use deionized water as water used for the post-cleaning treatment.

By performing the post-CMP cleaning treatment with the post-CMP cleaning composition according to one embodiment of the present invention, residues become extremely easy to remove. For this reason, by performing the post-CMP cleaning treatment (surface treatment) with the post-CMP cleaning composition according to one embodiment of the present invention, and then performing a further cleaning treatment using water, residues are extremely well removed.

### [Method for Manufacturing Semiconductor Substrate]

The post-CMP cleaning treatment method according to the present invention can be suitably applied in a case where the polished object to be polished is a polished semiconductor substrate. To be specific, the present invention is also to provide a method for manufacturing a semiconductor substrate, in which a polished object to be polished is a polished semiconductor substrate, the method including subjecting the polished semiconductor substrate to the post-CMP cleaning treatment method to reduce residues on a surface of the polished semiconductor substrate.

At this time, the polished object to be polished preferably contains a material containing a silicon-silicon bond (silicon material). To be specific, the present invention is also to provide a method for manufacturing a semiconductor substrate, in which a polished object to be polished is a polished semiconductor substrate, the method including: a polishing step of polishing a pre-polishing semiconductor substrate that contains a material containing a silicon-silicon bond (silicon material) using a polishing composition containing abrasive grains to obtain a polished semiconductor substrate; and a post-chemical mechanical polishing and cleaning treatment step of reducing residues containing the abrasive grains on a surface of the polished semiconductor substrate using the post-chemical mechanical polishing cleaning composition according to the present invention.

Details of the semiconductor substrate to which such a manufacturing method is applied are as described in the description of the polished object to be polished subjected to the post-CMP cleaning treatment (surface treatment) by the above post-CMP cleaning composition.

The method for manufacturing a semiconductor substrate is not particularly limited as long as it includes a step of subjecting the surface of a polished semiconductor substrate to post-CMP cleaning treatment using the post-CMP cleaning composition according to the present invention (post-CMP cleaning treatment step). Examples of such a manufacturing method may include a method comprising a polishing step for forming a polished semiconductor substrate and a cleaning step. Further, another example may include a method comprising, in addition to the polishing step and the cleaning step, a rinse polishing step between the polishing step and the cleaning step. Each of these steps will be described below.

### <Polishing Step>

The polishing step that can be included in the method for manufacturing a semiconductor substrate is a step of polishing a semiconductor substrate to form a polished semiconductor substrate.

The polishing step is a chemical mechanical polishing (CMP) step. Further, the polishing step may be a polishing step consisting of a single step or a polishing step consisting of a plurality of steps. Examples of the polishing step consisting of a plurality of steps may include a process of performing a finish polishing step after a preliminary polishing step (rough polishing step), a process of performing one or two or more secondary polishing steps after a primary polishing step and then performing a finish polishing step, and the like. The post-CMP cleaning treatment step using the post-CMP cleaning composition according to the present invention is preferably performed after the finish polishing step.

As the polishing composition, a known polishing composition can be appropriately used depending on characteristics of the semiconductor substrate. The polishing composition is not particularly limited, and examples thereof may include a polishing composition containing abrasive grains, a water-soluble polymer, a pH adjusting agent, and a solvent, and the like.

As a polishing apparatus, a general polishing apparatus that is equipped with a holder for holding an object to be polished, a motor capable of changing a rotation speed, and the like, and has a polishing table capable of attaching a polishing pad (polishing cloth) thereto can be used. As the polishing apparatus, either a single-side polishing apparatus or a double-side polishing apparatus may be used.

### <Post-Chemical Mechanical Polishing and Cleaning (Post-CMP Cleaning Treatment, Surface Treatment) Step>

The post-chemical mechanical polishing and cleaning step refers to a step of reducing residues on a surface of a polished object to be polished using the post-chemical mechanical polishing cleaning composition according to the present invention. In the method for manufacturing a semiconductor substrate, after the rinse polishing step, a cleaning step as a post-CMP cleaning treatment step may be performed, or only the rinse polishing step or only the cleaning step may be performed.

### (Rinse Polishing Step)

The rinse polishing step may be provided between the polishing step and the cleaning step in the method for manufacturing a semiconductor substrate. The rinse polishing step is a step of reducing foreign matters on a surface of a polished object to be polished (polished semiconductor substrate) by the post-CMP cleaning treatment method (rinse polishing treatment method) according to one embodiment of the present invention.

Details of the rinse polishing method used in the rinse polishing step are as described in the description regarding the rinse polishing treatment as above.

### (Cleaning Step)

The cleaning step may be provided after the polishing step or may be provided after the rinse polishing step in the method for manufacturing a semiconductor substrate. The cleaning step is a step of reducing foreign matters on a surface of a polished object to be polished (polished semiconductor substrate) by the post-CMP cleaning treatment method (cleaning method) according to one embodiment of the present invention.

Details of the cleaning method used in the cleaning step are the same as those in the (post-cleaning treatment) as above.

Although the embodiments of the present invention have been described in detail, it is clear that this is illustrative and exemplary and not restrictive, and that the scope of the present invention should be interpreted by the appended claims.

The present invention includes the following aspects and embodiments.

1. A post-chemical mechanical polishing cleaning composition containing the following components (A) and (B), and in which a pH is more than 7.0 and 10.0 or less:
Component (A): a nonionic polymer
Component (B): at least one compound selected from the group consisting of compounds having an amino group and a hydroxyl group, compounds represented by the following formula (1), and hexamethylenetetramine

H₂N[(CH₂)ₓNR¹]_{y}R² Formula (1):
wherein R¹ is each independently a hydrogen atom or an alkyl group having 1 to 10 carbon atoms; R² is a hydrogen atom or an alkyl group having 1 to 10 carbon atoms; x is each independently an integer of 1 or more and 10 or less; and y is an integer of 1 or more and 8 or less;
   2. The post-chemical mechanical polishing cleaning composition according to the above 1., in which the component (A) contains at least one nonionic polymer selected from the group consisting of polyvinyl alcohol, polyvinyl pyrrolidone, polyacrylamide, poly N-vinylacetamide, polyethylene glycol, hydroxyethyl cellulose, and a butenediol-vinyl alcohol copolymer, or is at least one compound selected from the group;
   3. The post-chemical mechanical polishing cleaning composition according to the above 1, or 2., in which the component (A) contains at least one nonionic polymer selected from the group consisting of polyvinyl alcohol, polyethylene glycol, hydroxyethyl cellulose, and a butenediol-vinyl alcohol copolymer, or is at least one compound selected from the group;
   4. The post-chemical mechanical polishing cleaning composition according to any one of the above 1. to 3., in which the component (B) contains at least one compound selected from the group consisting of 2-aminoethanol, 3-amino-1-propanol, diethanolamine, 2-(2-aminoethylamino)ethanol, 2-(methylamino)ethanol, 2-(2-aminoethoxy)ethanol, 3-amino-1,2-propanediol, 2-amino-1,3-propanediol, 2-amino-2-ethyl-1,3-propanediol, compounds represented by the formula (1), and hexamethylenetetramine, or is at least one compound selected from the group;
   5. The post-chemical mechanical polishing cleaning composition according to any one of the above 1. to 3., in which the component (B) contains at least one compound selected from the group consisting of 2-aminoethanol, 3-amino-1-propanol, 2-(2-aminoethylamino)ethanol, 2-(methylamino)ethanol, 3-amino-1,2-propanediol, 2-amino-1,3-propanediol, compounds represented by the formula (1), and hexamethylenetetramine, or is at least one compound selected from the group;
   6. The post-chemical mechanical polishing cleaning composition according to any one of the above 1. to 3., in which the component (B) contains at least one compound selected from the group consisting of compounds represented by the formula (1) and hexamethylenetetramine, or is at least one compound selected from the group;
   7. The post-chemical mechanical polishing cleaning composition according to any one of the above 4. to 6., in which the compound represented by the formula (1) is a compound represented by the formula (1) wherein R¹ is a hydrogen atom, a methyl group, an ethyl group, or an n-propyl group, R² is a hydrogen atom, a methyl group, an ethyl group, or an n-propyl group, x is 1 or more and 5 or less, and y is 1 or more and 8 or less;
   8. The post-chemical mechanical polishing cleaning composition according to any one of the above 4. to 6., in which the compound represented by the formula (1) is a compound represented by the formula (1) wherein R¹ is a hydrogen atom or a methyl group, R² is a hydrogen atom or a methyl group, x is 1 or more and 3 or less, and y is 1 or more and 5 or less;
   9. The post-chemical mechanical polishing cleaning composition according to any one of the above 4. to 6., in which the compound represented by the formula (1) is a compound represented by the formula (1) wherein R¹ is a hydrogen atom, R² is a hydrogen atom, x is 2, and y is 1 or more and 3 or less;
   10. The post-chemical mechanical polishing cleaning composition according to any one of the above 1. to 9., which is free of buffer represented by the formula: A-COO⁻NH₄⁺ (wherein A is an alkyl group having 1 to 10 carbon atoms or a phenyl group);
   11. The post-chemical mechanical polishing cleaning composition according to any one of the above 1. to 10., which is substantially composed of the component (A), the component (B), and at least one selected from the group consisting of a pH adjusting agent, an isothiazoline-based antiseptic agent, and water;
   12. The post-chemical mechanical polishing cleaning composition according to any one of the above 1. to 10., which is composed only of the component (A), the component (B), and at least one selected from the group consisting of a pH adjusting agent, an isothiazoline-based antiseptic agent, and water;
   13. A post-chemical mechanical polishing and cleaning treatment method which includes subjecting a polished object to be polished having a silicon-silicon bond to post-chemical mechanical polishing and cleaning treatment using the post-chemical mechanical polishing cleaning composition according to any one of the 1. to 12., to reduce residues on a surface of the polished object to be polished;
   14. The post-chemical mechanical polishing and cleaning treatment method according to the above 13., which is a rinse polishing treatment method or a cleaning treatment method;
   15. A method for manufacturing a semiconductor substrate, in which a polished object to be polished is a polished semiconductor substrate, which includes:
a polishing step of polishing a pre-polishing semiconductor substrate having a silicon-silicon bond using a polishing composition containing abrasive grains, to obtain a polished semiconductor substrate; and
a post-chemical mechanical polishing and cleaning treatment step of reducing residues containing the abrasive grains on a surface of the polished semiconductor substrate using the post-chemical mechanical polishing cleaning composition according to any one of the above 1. to 12.

### EXAMPLES

The present invention will be described in more detail with reference to the following examples and comparative examples. However, the technical scope of the present invention is not limited only to the following examples. Unless otherwise specified, “%” and “part” mean “% by mass” and “part by mass”, respectively. Further, in the following examples, unless otherwise specified, the operation was performed under the conditions of room temperature (25° C.)/relative humidity of 40% RH or more and 50% RH or less.

### [Provision of Components (A) to (D)]

The following components (A) to (D) were provided.

### <Component (A): Nonionic Polymer>

Polyvinyl alcohol (PVA) (product name JMR (registered trademark)-10HH manufactured by JAPAN VAM & POVAL Co., Ltd.; Mw=10,000)

### <Component (B): Amino Group-Containing Compound>

Hexamethylenetetramine (manufactured by Tokyo Chemical Industry Co., Ltd.; molecular weight 140)
Ethylenediamine (manufactured by Tokyo Chemical Industry Co., Ltd.; molecular weight 60)
Diethylenetriamine (manufactured by Tokyo Chemical Industry Co., Ltd.; molecular weight 103)
Triethylenetetramine (manufactured by Tokyo Chemical Industry Co., Ltd.; molecular weight 146)
2-aminoethanol (manufactured by Tokyo Chemical Industry Co., Ltd.; molecular weight 61)
3-amino-1-propanol (manufactured by Tokyo Chemical Industry Co., Ltd.; Molecular weight 75)
2-(2-aminoethylamino)ethanol (manufactured by Tokyo Chemical Industry Co., Ltd.; molecular weight 104)
3-amino-1,2-propanediol (manufactured by Tokyo Chemical Industry Co., Ltd.; molecular weight 91)
2-(2-aminoethoxy)ethanol (manufactured by Tokyo Chemical Industry Co., Ltd.; molecular weight 105)
2-amino-2-ethyl-1,3-propanediol (manufactured by Tokyo Chemical Industry Co., Ltd.; Molecular weight 119)
2-(methylamino)ethanol (manufactured by Tokyo Chemical Industry Co., Ltd.; molecular weight 75)
Diethanolamine (manufactured by Tokyo Chemical Industry Co., Ltd.; molecular weight 105)
2-amino-1,3-propanediol (manufactured by Tokyo Chemical Industry Co., Ltd.; molecular weight 91)

### <Component (B′): Other Amino Group-Containing Compound>

Ammonium acetate (manufactured by Kanto Chemical Co., Inc.; molecular weight 77)
Tetramethylammonium hydroxide (manufactured by Tokyo Chemical Industry Co., Ltd.); Molecular weight 91)
Tetrabutylammonium hydroxide (manufactured by Tokyo Chemical Industry Co., Ltd.); molecular weight 259)
Ethylamine (product name 33 wt % aqueous ethylamine solution manufactured by Tokyo Chemical Industry Co., Ltd.; molecular weight 45)

### <Component (C): pH Adjusting Agent>

Ammonia (product name: EL ammonia water (NH₃ concentration: 28.0% to 30.0%) manufactured by Kanto Chemical Co., Inc.; molecular weight 17)
Acetic acid (product name: acetic acid manufactured by Kanto Chemical Co., Inc.; molecular weight: 60)
Nitric acid (product name: nitric acid 69% manufactured by Kanto Chemical Co., Inc.; molecular weight: 63)
Potassium hydroxide (product name: 48% aqueous potassium hydroxide solution manufactured by Kanto Chemical Co., Inc.; molecular weight: 56).

### [Measurement of Weight Average Molecular Weight (Mw)]

As a weight average molecular weight (Mw) of the component (A), a weight average molecular weight (in terms of polyethylene glycol) measured by gel permeation chromatography (GPC) was used. The weight average molecular weight was measured by the following apparatus and conditions:
GPC apparatus: manufactured by SHIMADZU CORPORATION
Model: Prominence+ELSD detector (ELSD-LTII)
Column: VP-ODS (manufactured by SHIMADZU CORPORATION)
Mobile phase A: MeOH
   B: 1% acetic acid aqueous solution
Flow rate: 1 mL/min
Detector: ELSD temp. 40° C., Gain 8, N₂GAS 350 kPa
Oven temperature: 40° C.
Injection volume: 40 μL.

### [Measurement of Electrical Conductivity (EC)]

Electrical conductivity of the post-chemical mechanical polishing cleaning composition was measured using a tabletop electrical conductivity meter (manufactured by HORIBA, Ltd., model number: DS-71).

### [Measurement of pH of Post-Chemical Mechanical Polishing Cleaning Composition]

A pH of the post-chemical mechanical polishing cleaning composition (liquid temperature: 25° C.) was confirmed by a pH meter (product name: LAQUA (registered trademark) manufactured by HORIBA, Ltd.). The pH of the polishing composition described below was also measured by the same method.

### [Preparation of Post-Chemical Mechanical Polishing Cleaning Composition (Post-CMP Cleaning Composition)]

### Example 1

A post-CMP cleaning composition 1 was prepared by mixing and stirring polyvinyl alcohol (PVA) (Mw=10,000) as the component (A), hexamethylenetetramine as the component (B), ammonia as the component (C), and distilled water as a solvent at 25° C. for 5 minutes.

A content of each component was as follows: a content of the component (A) was set to 0.06% by mass (0.6 g/L), a content of the component (B) was set to 0.100% by mass (7.1 mM), based on a total amount of the post-CMP cleaning composition 1, and a content of the component (C) (pH adjusting agent) was set so as to make pH of the post-CMP cleaning composition 1 9.2.

### Examples 2 to 20, Comparative Examples 1 to 13

Post-CMP cleaning compositions 2 to 33 were prepared in the same manner as in Example 1, except that the component (A), the component (B)/(B′), the component (C) and the pH were changed as described in Table 1, respectively. A concentration of the component (B)/(B′) in the post-CMP cleaning compositions 2 to 20 and 22 to 33 was set to 7.1 mM, and a concentration of the component (B)/(B′) in the post-CMP cleaning composition 21 was set to 3.7 mM.

The post-CMP cleaning compositions 1 to 33 prepared above were free of abrasive grains (content of abrasive grains=0% by mass).

TABLE 1

| | | Component (A) | | Component (B)/(B′) | | | Component | |
|---|---|---|---|---|---|---|---|---|
| | Post-CMP | | Content | | | Content | (C) | |
| | cleaning | | [% by | | Concentration | [% by | pH adjusting | |
| | composition | Compound | mass] | Compound | [mM] | mass] | agent | pH |
| Example 1 | 1 | PVA | 0.06 | Hexamethylenetetramine | 7.1 | 0.100 | Ammonia | 9.2 |
| Example 2 | 2 | PVA | 0.06 | Ethylenediamine | 7.1 | 0.043 | Acetic acid | 9.2 |
| Example 3 | 3 | PVA | 0.06 | Diethylenetriamine | 7.1 | 0.074 | Acetic acid | 9.2 |
| Example 4 | 4 | PVA | 0.06 | Triethylenetetramine | 7.1 | 0.104 | Acetic acid | 9.2 |
| Example 5 | 5 | PVA | 0.06 | 2-aminoethanol | 7.1 | 0.044 | Acetic acid | 9.2 |
| Example 6 | 6 | PVA | 0.06 | 3-amino-1-propanol | 7.1 | 0.054 | Acetic acid | 9.1 |
| Example 7 | 7 | PVA | 0.06 | 2-(2-aminoethylamino)ethanol | 7.1 | 0.074 | Acetic acid | 9.2 |
| Example 8 | 8 | PVA | 0.06 | 3-amino-1,2-propanediol | 7.1 | 0.065 | — | 9.1 |
| Example 9 | 9 | PVA | 0.06 | 2-(2-aminoethoxy)ethanol | 7.1 | 0.075 | Acetic acid | 9.2 |
| Example 10 | 10 | PVA | 0.06 | 2-Amino-2-ethyl-1,3-propanediol | 7.1 | 0.085 | Ammonia | 9.2 |
| Example 11 | 11 | PVA | 0.06 | 2-(Methylamino)ethanol | 7.1 | 0.054 | Acetic acid | 9.1 |
| Example 12 | 12 | PVA | 0.06 | Diethanolamine | 7.1 | 0.075 | Ammonia | 9.2 |
| Example 13 | 13 | PVA | 0.06 | 2-amino-1,3-propanediol | 7.1 | 0.065 | Ammonia | 9.2 |
| Example 14 | 14 | PVA | 0.06 | Diethylenetriamine | 7.1 | 0.074 | Acetic acid | 7.2 |
| Example 15 | 15 | PVA | 0.06 | Diethylenetriamine | 7.1 | 0.074 | Acetic acid | 7.5 |
| Example 16 | 16 | PVA | 0.06 | Diethylenetriamine | 7.1 | 0.074 | Acetic acid | 8.0 |
| Example 17 | 17 | PVA | 0.06 | Diethylenetriamine | 7.1 | 0.074 | Acetic acid | 8.5 |
| Example 18 | 18 | PVA | 0.06 | Diethylenetriamine | 7.1 | 0.074 | — | 9.0 |
| Example 19 | 19 | PVA | 0.06 | Diethylenetriamine | 7.1 | 0.074 | Ammonia | 9.5 |
| Example 20 | 20 | PVA | 0.06 | Diethylenetriamine | 7.1 | 0.074 | Ammonia | 9.9 |
| Comparative | 21 | PVA | 0.06 | Ammonium acetate | 3.7 | 0.029 | Ammonia | 9.2 |
| Example 1 | | | | | | | | |
| Comparative | 22 | PVA | 0.06 | Tetramethylammonium | 7.1 | 0.065 | Acetic acid | 9.2 |
| Example 2 | | | | hydroxide | | | | |
| Comparative | 23 | PVA | 0.06 | Tetrabutylammonium hydroxide | 7.1 | 0.185 | Acetic acid | 9.2 |
| Example 3 | | | | | | | | |
| Comparative | 24 | PVA | 0.06 | Ethylamine | 7.1 | 0.032 | Acetic acid | 9.2 |
| Example 4 | | | | | | | | |
| Comparative | 25 | PVA | 0.06 | Diethylenetriamine | 7.1 | 0.074 | Nitric acid | 3.0 |
| Example 5 | | | | | | | | |
| Comparative | 26 | PVA | 0.06 | Diethylenetriamine | 7.1 | 0.074 | Nitric acid | 4.0 |
| Example 6 | | | | | | | | |
| Comparative | 27 | PVA | 0.06 | Diethylenetriamine | 7.1 | 0.074 | Nitric acid | 5.0 |
| Example 7 | | | | | | | | |
| Comparative | 28 | PVA | 0.06 | Diethylenetriamine | 7.1 | 0.074 | Nitric acid | 6.0 |
| Example 8 | | | | | | | | |
| Comparative | 29 | PVA | 0.06 | Diethylenetriamine | 7.1 | 0.074 | Nitric acid | 6.5 |
| Example 9 | | | | | | | | |
| Comparative | 30 | PVA | 0.06 | Diethylenetriamine | 7.1 | 0.074 | Ammonia | 10.5 |
| Example 10 | | | | | | | | |
| Comparative | 31 | PVA | 0.06 | Diethylenetriamine | 7.1 | 0.074 | KOH | 11.0 |
| Example 11 | | | | | | | | |
| Comparative | 32 | PVA | 0.06 | Diethylenetriamine | 7.1 | 0.074 | KOH | 12.0 |
| Example 12 | | | | | | | | |
| Comparative | 33 | PVA | 0.06 | Diethylenetriamine | 7.1 | 0.074 | KOH | 13.0 |
| Example 13 | | | | | | | | |

### [Provision of Polished Object to be Polished]

A polished amorphous silicon substrate which had been polished by the following chemical mechanical polishing (CMP) step was provided.

### (CMP Step)

As an object to be polished, a silicon wafer (amorphous silicon substrate) (300 mm wafer, manufactured by Advanced Materials Technology, Inc.) on which an amorphous silicon film of 2000 Å in thickness was formed by CVD was provided.

The amorphous silicon substrate provided above was polished under the following conditions using a polishing composition having the following composition, to obtain a polished object to be polished (polished amorphous silicon substrate).

### <Polishing Composition>

First, a silica slurry having the following composition was prepared:
Colloidal silica (average primary particle size: 35 nm, average secondary particle size: 70 nm) 2.5% by mass
Polyvinylpyrrolidone (product name: PITZCOL (registered trademark) K30A manufactured by DKS Co. Ltd.; Mw=45,000) 0.0625% by mass
Ammonia (product name EL ammonia water (NH₃ concentration: 28.0% to 30.0%) manufactured by Kanto Chemical Co., Inc.) 0.0825% by mass (in terms of NH₃)
Solvent: distilled water.

The pH of the obtained polishing composition was 10.0.

### <Polishing Apparatus and Polishing Conditions>

Polishing apparatus: REFLEXION (registered trademark) LK (manufactured by Applied Materials, Inc.)
Polishing pad: foamed polyurethane pad IC1010 manufactured by ANCHOR TECHNO. LTD
Conditioner (dresser): Diamond pad conditioner (3M-A165 Conditioner Disk, manufactured by 3M Company)
Polishing pressure: 1.0 psi (1 psi=6894.76 Pa, same below)
Rotation speed of polishing table: 83 rpm
Rotation speed of head: 77 rpm
Supply of polishing composition: continuous pouring and flowing
Supply amount of Polishing composition: 200 mL/min
Polishing time: 30 seconds.

### [Rinse Polishing Treatment]

After each surface of the object to be polished (amorphous silicon substrate) was polished in the CMP step, the polished object to be polished (polished amorphous silicon substrate) was removed from the polishing table (platen). Subsequently, the polished object to be polished was mounted on another polishing table (platen) in the same polishing apparatus, and rinse polishing treatment was performed on the surface of the polished object to be polished using each post CMP cleaning composition 1 to 33 under the following conditions.

### <Rinse Polishing Apparatus and Rinse Polishing Conditions>

Polishing apparatus: REFLEXION (registered trademark) LK (manufactured by Applied Materials, Inc.)
Polishing pad: foamed polyurethane pad H800 Type-1 (3-1S) manufactured by Fujibo Ehime Co., Ltd.
Conditioner (dresser): nylon brush manufactured by 3M Company
Polishing pressure: 1.0 psi
Rotation speed of table: 83 rpm
Rotation speed of head: 77 rpm
Supply of post-CMP cleaning composition: continuous pouring and flowing
Supply amount of Post CMP cleaning composition: 300 mL/min
Polishing time: 60 seconds.

### [Post-Cleaning Treatment]

After the rinse polishing treatment, the substrate surface was cleaned with brush for 30 seconds using a 0.3% NH₃ aqueous solution, and then washed with deionized water for 20 seconds, to obtain a rinse-polished object to be polished (rinse-polished amorphous silicon substrates 1 to 33 using the post-CMP cleaning compositions 1 to 33 of examples and comparative examples).

### [Evaluation]

### (Residue Evaluation)

The number of residues on the surface of the rinse-polished object to be polished (each of rinse-polished amorphous silicon substrates 1 to 33) was evaluated using an optical inspection machine Surfscan (registered trademark) SP5 manufactured by KLA-Tencor Corporation.

Specifically, the number of residues having a diameter of more than 40 nm was counted for a remaining portion excluding a portion having a width of 3 mm from the outer peripheral end portion (a region from 0 mm to 3 mm when an outer peripheral end portion is 0 mm) of one surface of the rinse-polished amorphous silicon substrate. Thereafter, for the rinse-polished amorphous silicon substrate, the number of abrasive grain residues and the number of organic residues were measured by SEM observation using Review SEM RS6000 manufactured by Hitachi High-Tech Corporation. First, the number of residues present in the remaining portion excluding the portion having a width of 5 mm from the outer peripheral end portion of one surface of the rinse-polished amorphous silicon substrate was counted by SEM observation. Next, the type of residues (an abrasive grain or an organic residue) was identified by visual SEM observation, and the number of the abrasive grain residues (SiO₂ residues) and the number of the organic residues (pad debris, polymers, and the like) were measured.

The total number of residues (the sum of the number of abrasive grain residues and the number of organic residues) is preferably as small as possible. As an example, the total number of residues of 29 or less is acceptable. It is preferably 25 or less, more preferably 19 or less, and particularly preferably 15 or less.

The number of abrasive grain residues (SiO₂ residues) is preferably as small as possible. As an example, the number of abrasive grain residues (SiO₂ residues) of 15 or less is acceptable. It is preferably 12 or less, more preferably 10 or less, and particularly preferably 8 or less.

The number of organic residues (pad scraps, polymers, and the like) is preferably as small as possible. As an example, the number of organic residues (pad scraps, polymers, and the like) of 10 or less is acceptable. It is preferably 9 or less, more preferably 8 or less, and particularly preferably 7 or less.

The results of each of the above evaluations are shown in Table 2 below.

TABLE 2

| | | Number of defects (A-Si > 40 nm) | | |
|---|---|---|---|---|
| | | | Abrasive | |
| | Electrical | | grain | Organic |
| | conductivity | Total | residues | residues |
| | [mS/cm] | [count] | [count] | [count] |
| Example 1 | 0.40 | 15 | 8 | 7 |
| Example 2 | 0.47 | 12 | 6 | 6 |
| Example 3 | 0.67 | 11 | 7 | 4 |
| Example 4 | 0.61 | 11 | 7 | 4 |
| Example 5 | 0.40 | 20 | 11 | 9 |
| Example 6 | 0.47 | 18 | 10 | 8 |
| Example 7 | 0.30 | 20 | 10 | 10 |
| Example 8 | 0.27 | 20 | 11 | 9 |
| Example 9 | 0.32 | 22 | 12 | 10 |
| Example 10 | 0.30 | 21 | 12 | 9 |
| Example 11 | 0.44 | 19 | 11 | 8 |
| Example 12 | 0.33 | 21 | 12 | 9 |
| Example 13 | 0.39 | 20 | 11 | 9 |
| Example 14 | 1.22 | 9 | 5 | 4 |
| Example 15 | 1.20 | 9 | 5 | 4 |
| Example 16 | 1.14 | 10 | 6 | 4 |
| Example 17 | 1.00 | 10 | 6 | 4 |
| Example 18 | 0.70 | 11 | 6 | 5 |
| Example 19 | 0.35 | 12 | 7 | 5 |
| Example 20 | 0.31 | 16 | 9 | 7 |
| Comparative | 0.41 | 35 | 22 | 13 |
| Example 1 | | | | |
| Comparative | 0.40 | 34 | 22 | 12 |
| Example 2 | | | | |
| Comparative | 0.40 | 34 | 22 | 12 |
| Example 3 | | | | |
| Comparative | 0.40 | 36 | 23 | 13 |
| Example 4 | | | | |
| Comparative | 2.63 | 37 | 24 | 13 |
| Example 5 | | | | |
| Comparative | 2.18 | 36 | 23 | 13 |
| Example 6 | | | | |
| Comparative | 1.68 | 35 | 23 | 12 |
| Example 7 | | | | |
| Comparative | 1.54 | 34 | 22 | 12 |
| Example 8 | | | | |
| Comparative | 1.54 | 31 | 22 | 11 |
| Example 9 | | | | |
| Comparative | 0.70 | 30 | 19 | 11 |
| Example 10 | | | | |
| Comparative | 0.53 | 33 | 21 | 12 |
| Example 11 | | | | |
| Comparative | 0.98 | 40 | 26 | 14 |
| Example 12 | | | | |
| Comparative | 8.12 | 45 | 28 | 17 |
| Example 13 | | | | |

As is apparent from the Table 2, it can be noted that the post-CMP cleaning compositions of examples can more efficiently remove residues on the amorphous silicon substrate as compared with the post-CMP cleaning compositions of comparative examples. The results are results evaluated immediately after production of the post-CMP cleaning composition, but where the composition is to be preserved or stored for extended periods of time, it preferably contains an antiseptic agent (antifungal agent). The antiseptic agent (antifungal agent) has little or no effects on the results. Accordingly, it is considered that the post-CMP cleaning composition containing an antiseptic agent (antifungal agent) also has the same results as described above.

What is claimed is:

1. A post-chemical mechanical polishing cleaning composition comprising the following components (A) and (B), and having a pH of more than 7.0 and 10.0 or less:
Component (A): a nonionic polymer
Component (B): at least one compound selected from the group consisting of a compound having an amino group and a hydroxyl group, a compound represented by the following formula (1), and hexamethylenetetramine
H₂N[(CH₂)ₓNR¹]_{y}R² Formula (1):
in the formula (1), R¹ is each independently a hydrogen atom or an alkyl group having 1 to 10 carbon atoms; R² is a hydrogen atom or an alkyl group having 1 to 10 carbon atoms; x is each independently an integer of 1 or more and 10 or less; and y is an integer of 1 or more and 8 or less.

2. The post-chemical mechanical polishing cleaning composition according to claim 1, wherein the component (A) contains at least one nonionic polymer selected from the group consisting of polyvinyl alcohol, polyvinyl pyrrolidone, polyacrylamide, poly N-vinylacetamide, polyethylene glycol, hydroxyethyl cellulose, and a butenediol-vinyl alcohol copolymer.

3. The post-chemical mechanical polishing cleaning composition according to claim 1, wherein the component (B) contains at least one compound selected from the group consisting of the compound represented by the formula (1) and hexamethylenetetramine.

4. The post-chemical mechanical polishing cleaning composition according to claim 1, which is free of a buffer represented by the formula: A-COO⁻NH₄⁺ (wherein A is an alkyl group having 1 to 10 carbon atoms or a phenyl group).

5. The post-chemical mechanical polishing cleaning composition according to claim 1, which is substantially composed of the component (A), the component (B), and at least one selected from the group consisting of a pH adjusting agent, an isothiazoline-based antiseptic agent, and water.

6. A post-chemical mechanical polishing and cleaning treatment method comprising: subjecting a polished object to be polished having a silicon-silicon bond to post-chemical mechanical polishing and cleaning treatment using the post-chemical mechanical polishing cleaning composition set forth in claim 1, to reduce residues on a surface of the polished object to be polished.

7. The post-chemical mechanical polishing and cleaning treatment method according to claim 6, being a rinse polishing treatment method or a cleaning treatment method.

8. A method for manufacturing a semiconductor substrate, wherein a polished object to be polished is a polished semiconductor substrate, and the method comprising:
polishing a pre-polishing semiconductor substrate having a silicon-silicon bond using a polishing composition containing abrasive grains to obtain a polished semiconductor substrate; and
subjecting the polished semiconductor substrate to post-chemical mechanical polishing and cleaning treatment using the post-chemical mechanical polishing cleaning composition set forth in claim 1, to reduce residues containing the abrasive grains on a surface of the polished semiconductor substrate.
